(19) United States
(12) Patent Application Publication
(10) Pub. No.: US 2011/0163744 A1
(43) Pub. Date: Jul. 7, 2011

(54) CELLULAR TISSUE MAGNETIC SIGNAL DETECTING APPARATUS

(75) Inventors: Shinsuke Nakayama, Nagoya-shi (JP); Tsuyoshi Uchiyama, Nagoya-shi (JP); Kaneo Mouri, Nagoya-shi (JP)

(73) Assignee: NATIONAL UNIVERSITY CORPORATION NAGOYA UNIVERSITY, Nagoya-shi, Aichi (JP)

(21) Appl. No.: 12/988,525

(22) PCT Filed: Nov. 8, 2008
(86) PCT No.: PCT/JP2008/070357

§ 371 Date: Mar. 17, 2011

(30) Foreign Application Priority Data
Apr. 21, 2008 (JP) 2008-133642
Jul. 1, 2008 (JP) 2008-196993

(51) Int. Cl. G01R 33/02

(52) U.S. Cl. 324/249; 324/252

(57) ABSTRACT

A cellular tissue magnetic signal detecting device for detecting a magnetic signal locally generated in a cellular tissue including an excitable cell generating an electrical excitation, the cellular tissue magnetic signal detecting device includes: a magnetic sensor head operative to approach the cellular tissue within 1000 μm; and a magnetic detecting section detecting the magnetic signal with a resolution of 1000 μm or less at a noise level of 1 nT or less, and a response speed of 1 ms or less based on an output signal from the magnetic sensor head; the magnetic sensor head including magneto impedance sensor.

### TECHNICAL FIELD

The present invention relates to cellular tissue magnetic signal detecting devices for detecting magnetic signals locally generated in cellular tissues including excitable cells operative to generate electrical excitations and, more particularly, to a cellular tissue magnetic signal detecting device for detecting a magnetic signal in a contactless and noninvasive manner with respect to a cellular tissue serving as a detection object.

### BACKGROUND ART

A biological body (living body) has various electrically excitable cells such as nerve, muscle and endocrine cells or the like. Membrane potential changes occur in the electrically excitable cells due to activation of an ion transporter across a cell membrane, i.e., due to an ion flow. The electrically excitable cells such as the nerve, muscle and endocrine cells or the like, which are present in the biological body, perform distinctive electrical activities depending on respective functions. Cellular tissues, including such electrically excitable cells, serve tissues of kinds different from each other in conjunction with functions and roles of the biological body. For instance, FIG. 1 represents record of intercellular potential, recorded on various cellular tissues, which are described in Non-Patent Publication 5. As shown in FIG. 1, a cardiac pacemaker cell repeatedly performs spontaneous electrical excitations ((A) of the same figure). Meanwhile, a ventricular muscle cell generates a potential remarkably different in form due to induction caused by an electrical trigger from the environment ((B) of the same figure).

Further, drugs, compounds or food ingredients or the like act on the cellular tissues including electrically excitable cells to cause the cellular tissues to perform the electrical activities depending on acting drugs or the like. Therefore, if it is possible to perform screening evaluation on the activity of the cellular tissue in a short time under a circumstance where the drugs, the compounds or the food ingredients or the like are administered into the cellular tissue, development of the drug acting on the excitable cell can be increasingly promoted. Further, with important disorders such as, for instance, nerve degenerations of Alzheimer's disease or Parkinson's disease, necrosis of ventricular muscle on myocardial infarction and dysfunction of Pancreatic Langerhans islet beta cells on diabetes, differences occur in the cellular tissues including the electrically excitable cells. Thus, it has been expected to develop a device for observing the electrical activity of the cellular tissue in order to evaluate a state of the cellular tissue.

For evaluating the state of the cellular tissue, many attempts have been made in the related art employing a technology of measuring each cellular tissue using a detecting needle having a size of micrometer (μm) (i.e., a microprobe such as a glass microelectrode and a patch clamp electrode or the like) with magnifying the cellular tissue using a microscope of dozens times magnifications. However, such a technology depends highly on skills of an individual surveyor and, hence, a difficulty is encountered in establishing such a technology to be an objective technique.

Meanwhile, for the cellular tissues to be utilized for regenerative medicine and drug development, it has been hoped to establish a technology of causing a master cell, capable of differentiating into a wide variety of cells such as Embryonic-Stem (ES) cell and induced-Pluripotent Stem (iPS) cell, and a stem cell capable of differentiating into a specified group, to be induced into cell tissues in specified objects. This is because, owing to an ability of the iPS cell differentiating into various cells, there is likelihood that the iPS cell grows up to be a teratomas in which a wide variety of tissues such as nerve, muscle, upper skin and lipid cells or the like are present mixedly as parts within a common tissue as shown in FIG. 2. FIG. 2 is based on drawings described in Non-Patent Publication 6. In such a case, to establish a technology of identifying either one of the cellular tissues to be reliably induced, a part having a possibility to be an intended cellular tissue needs to be identified among the wide variety of tissues partly present in the common tissue. As set forth above, further, it is considered that the part with the possibility to be the intended cellular tissue is identified based on the electrical activity depending on a function of the electrically excitable cell. For such an intended purpose, a need arises to detect the electrical activity in contactless and noninvasive manner with respect to the cellular tissue serving as a detection object.

Non-Patent Publication 1 and Non-Patent Publication 2 disclose methods of utilizing an experimental bath having a lower surface provided with a microelectrode at multiple points as a method of efficiently detecting an activity potential change in a minute cellular tissue in a low-invasive fashion. Furthermore, Non-Patent Publication 3 and Non-Patent Publication 4 disclose a method of utilizing an optical signal related to a membrane voltage-sensitive dye as a method of efficiently detecting an activity potential change in a minute cellular tissue in a low-invasive fashion. In addition, Patent Publication 1 discloses a device for detecting a magnetic change (fluctuation) occurring in a cellular tissue by utilizing SQUID (Superconducting Quantum Interference Device).
Patent Document 1: Japanese Patent Publication 2004-219109
Non-Patent Document 1: Shimono, K., Brucher, F., Granger, R., Lynch, G., & Taketani, M., “Origins and Distribution of Cholinergically Induced β Rhythms in Hippocampal Slices”, The Journal of Neuroscience, 2000, No. 20, p. 8462-8473
Non-Patent Document 2: Nakayama, S., Shimono, K., Liu, H.-N., Jiko, H., Katayama, N., Tomita, T. & Goto, K., “Pacemaker phase shift in the absence of neural activity in guinea-pig stomach: a microelectrode array study”, The Journal of Physiology, 2006, No. 576, p. 727-738
Non-Patent Document 3: Kamino, K., Komuro, H., Sakai, T., & Sato, K., “Optical assessment of spatially ordered patterns of neural response to vagal stimulation in the early embryonic chick brainstem”, Neuroscience Research, 1990, No. 8, p. 255-271
Non-Patent Document 4: Zochowski, M., Wachowiak, M., Falk, C. X.., Cohen, L. B., Lam, Y. W., Antic, S., & Zecevic, D., “Imaging Membrane Potential With Voltage-Sensitive Dyes”, Biological Bulletin, 2000, No. 198, p. 1-21
Non-Patent Document 5: Hille, B, “Ion Channels of Excitable Membranes”, 3rd Edition, USA, Sinauer Associates Inc, Sunderland, 2001
Non-Patent Document 6: Takahashi, K., Tanabe, K., Ohnuki, M., Narita, M., Ichisaka, T., Tomoda, K., & Yamanaka, S., “Induction of Pluripotent Stem Cells from Adult Human Fibroblasts by Defined Factors”, Cell, 2007, No. 131, p. 834-835
Non-Patent Document 7: Takaki, M., Nakayama, S., Misawa, H., Nakagawa, T. & Kuniyasu, H., “In Vitro Formation of Enteric Neural Network Structure in a Gut-Like Organ Differentiated from Mouse Embryonic Stem Cells”, Stem Cells, 2006, No. 24, p. 1414-1422
Non-Patent Document 8: Nakayama S, Ohya Y and Imaizumi Y. 2004. Characterization into gastrointestinal pacemaker mechanism using cultured cell cluster preparation. Folia Pharmacologica Japonica 123, 149-154.
Non-Patent Document 9: Ganong W F. 2000. Excitable tissue: Nerve. In Review of Medical Physiology, Chapter 2. McGraw-Hill, New York.
Non-Patent Document 10: Tsuyoshi Uchiyama, Shingo Tajima, and Ji Li “Non-contact heart rate detection method using MI micro magnetic sensor”, Proc. of Magnetics Committee of Institute of Electrical Engineers of Japan, 2007, MAG-07-108
Non-Patent Document 11: Kaneo Mouri “Science and Engineering of Magnetic Sensors”, Corona Corporation, 1998

### DISCLOSURE OF THE INVENTION

### Problems to be Solved

FIG. 3 is a view illustrating one example of a device for realizing the method of efficiently detecting the activity potential change in the minute cellular tissue in a low invasive fashion upon utilizing the experimental bath having the lower surface provided with the microelectrode at the multiple points disclosed in Non-Patent Publication 1 or Non-Patent Publication 2 mentioned above. FIG. 3 is a view showing a culture vessel, when viewed from the above, in which one well (experimental bath) 112, located in the culture vessel, has a bottom surface provided with four minute electrodes (microelectrodes) 116. An activity potential change of the cellular tissue 114 held in contact with either one of the electrodes 116 among cellular tissues 114 present in the well 112, is detected using a detection circuit or the like that is not shown. With the device of FIG. 3, however, since the detection cannot be performed if the cellular tissue 114 is not held in direct contact with the electrode 116, there is an issue where a state i.e., an electrical activity of only the cellular tissue 114 in contact with the electrode 116 can be detected. In addition, another issue arises in a difficulty caused in separating the cellular tissue 114 from the electrode 116 after the detection has been executed.

FIG. 4 is a view illustrating an example of a device for realizing the method of efficiently detecting the activity potential change in the minute cellular tissue in the low invasive fashion with utilizing the optical signal related to the membrane voltage-sensitive dye disclosed in Non-Patent Publication 3 or Non-Patent Publication 4 mentioned above. The membrane voltage-sensitive dye is a substance, causing a fluorescence change or the like to occur in the cellular tissue depending on the potential change thereof, which is used as an optical probe for measuring the activity of the cell. In FIG. 4, more particularly, membrane voltage-sensitive dyes are added as the optical probes onto the cellular tissues 114 (114a and 114b) in one well (experimental bath) 112′ provided in the culture vessel. In this way, by detecting a difference in fluorescence of the cellular tissues 114, i.e., a difference between, for instance, cellular tissues 114a and 114b shown in FIG. 4, the activity potentials occurring in the cellular tissues 114 can be detected.

However, the membrane voltage-sensitive dye has likelihood that depending on measuring conditions, a biological signal is improperly converted into an optical signal, i.e., mismatching occurs between the potential of the cellular tissue and the degree of fluorescence. Further, another issue arises in that the amounts of dyes introduced into the cellular tissues are different depending on the cells. Furthermore, the cellular tissues frequently suffer from damages due to exposure to loads of the optical probes, i.e., due to the membrane voltage-sensitive dyes being added. Moreover, there are many difficulties encountered in use of the optical probe. That is, among the optical probes, especially, a supersensitive membrane voltage-sensitive dye is slow in response to an electric signal and a membrane voltage-sensitive dye having a relatively fast response to an electric signal has a low sensitivity, then there are problems of difficulty in obtaining a stable result. These issues are also involved in Non-Patent Publication 7 presented by the present inventors. With Non-Patent Publication 7, in actual practice, it has been difficult to obtain stable results on every specimens during experimental tests for making evaluation for induction results of a nerve cell in which the nerve cell is induced into an intestinal tract like cellular tissue, induced from the ES cell, and the optical probe responsive to intracellular Ca is used. Such cause may be derived from damage to the cellular tissue due to the contact with the optical probe per se or color fading of the optical probe or the like. In addition, increase of intracellular Ca (calcium) and a subsequent normalization occur at slow speed and it has been difficult to evaluate reactions in nerve activity pulse trains or the like repeatedly appearing in the order of ms (millisecond) intervals.

FIG. 5 is a view indicated in a perspective view for illustrating an example of the device for detecting the magnetic fluctuation occurring in the cellular tissue by utilizing SQUID (Superconducting Quantum Interference Device) disclosed in Patent Publication 1 mentioned above. According to the device utilizing such SQUID, it becomes possible to avoid the occurrence of damage to the cellular tissue in the course of measurements unlike the method of using the microelectrode 116 as stated above or the method of using the optical probe. In FIG. 5, the culture vessel has one well (experimental bath) 112 with the lower area provided with a magnetic sensor 118 employing SQUID to detect the magnetic signal generated by the cellular tissues 114 placed in the well 112. FIG. 6 is a view illustrating one example of an overall structure of the detection device utilizing SQUID of FIG. 5. As shown in FIG. 6, the magnetic sensor (SQUID sensor) 118 is kept by liquid nitrogen holder and a cryostat 120 under ultracold environment.

In order to sustain the cellular tissues 114 serving as the detection object in view of a living temperature, a need arises for the magnetic sensor 118, placed under the ultracold temperature state, and the cellular tissues 114 to be placed in an adequately isolated distance “d”. However, the intensity of the magnetic field decreases as the square or the triplicate of the distance. Thus, even when using a highly sensitive magnetic sensor 118, a difficulty is encountered in conducting the measurement with the best use of such sensitivity because of a need arising to ensure the isolated distance “d”. Further, the spatial resolution decreases as the square of the distance between the magnetic sensor 118 and the cellular tissue 114, resulting in a difficulty of evaluating a state of a localized area in measuring the cellular tissue serving as the detection object. That is, the magnetic sensor 118 measures the cellular tissue 114 in a position away therefrom. Thus, even if there are magnetic signals partly generated from the cellular tissues 114 at parts thereof, the magnetic signals generated from all of the cellular tissues 114 are detected in confusion and it becomes difficult to detect a position of a particular cellular tissue which generates a particular magnetic signal, from among the cellular tissues 114.

FIG. 7 is a view, representing a spontaneous magnetic activity of a cardiac muscle culture cell tissue detected by utilizing the detection device shown in FIG. 6, which is described in a literature (entitled “Measurement of the signal from a cultured cell using a high-Tc SQUID”, Superconductor Science and Technology, issue 2003, Volume 16, pp. 1536-1539, in FIG. 7) presented by the inventors of the subject invention related to Patent Publication 1. As shown in FIG. 7, with the detection device utilizing SQUID, only an irregular spontaneous magnetic activity waveform is recorded.

### SUMMARY OF THE INVENTION

The present invention has been made in light of the background art discussed above and has an object to provide a cellular tissue magnetic signal detecting device for detecting magnetic signals locally generated in a cellular tissue including an excitable cell operative to generate electrical excitation and provide a cellular tissue magnetic signal detecting device enabling the cellular tissue to be detected in contactless and noninvasive manner with sufficient spatial resolution.

### Means for Solving the Problem

The object indicated above can be achieved according to a first aspect of the present invention, which provides (a) a cellular tissue magnetic signal detecting device for detecting a magnetic signal locally generated in a cellular tissue including an excitable cell generating an electrical excitation, the cellular tissue magnetic signal detecting device including: (b) a magnetic sensor head operative to approach the cellular tissue within 1000 μm; and a magnetic detecting section detecting the magnetic signal with a resolution of 1000 μm or less at a noise level of 1 nT or less and a response speed of 1 ms or less based on an output signal from the magnetic sensor head.

According to the first aspect of the present invention, the magnetic detecting section includes the magnetic sensor heads which can approach the cellular tissue within 1000 μm or less, and the magnetic detecting section can detect the magnetic signals with a resolution of 1000 μm or less at a noise level of 1 nT or less with a response speed of 1 ms or less based on the output signals delivered from the magnetic sensor heads. Thus, the cellular tissue magnetic signal detecting device enables the locally generated magnetic signal to be detected in the cellular tissue, including the excitable cell, in a contactless and noninvasive manner with respect to the cellular tissue with a sufficient spatial resolution.

Preferably, (a) the magnetic detecting section includes the first magnetic sensor head and the second magnetic sensor head which is disposed to be longer in distance from the cellular tissue than the distance between the cellular tissue and the first magnetic sensor head, and the magnetic detecting section further includes the environmental magnetic field canceling section for eliminating the influence of the environmental magnetic field based on the magnetic signals detected by the first magnetic sensor head and the second magnetic sensor head. Thus, the environmental magnetic field canceling section can eliminate the influence of the environmental magnetic field based on the magnetic signals detected by the first magnetic sensor head and the second magnetic sensor head, respectively, and, accordingly, in addition to the above-mentioned effects, the magnetic signal generated by the cellular tissue with increased precision can be detected.

Preferably, the magnetic sensor heads include the columnar magnetic bodies. Thus, with the magnetic sensor heads including the columnar magnetic bodies, this allows the magnetic sensor heads to be provided with performances required for detecting the magnetic signals while permitting the magnetic sensor heads to be placed closer to the cellular tissue serving as the detection object in a distance needed for realizing a desired spatial resolution.

Preferably, the magnetic sensor heads include the tabular magnetic body or the thin film-like magnetic body. Thus, with the magnetic sensor heads including the tabular magnetic body or the thin film-like magnetic body, the magnetic sensor heads can be provided with performances required for the detection of the magnetic signals, and the magnetic sensor heads can be placed closer to the cellular tissue serving as the detection object in a distance required for realizing a desired spatial resolution.

Preferably, the magnetic sensor heads include the magnetic bodies of the mesh-like structure. This result in a capability of providing the magnetic sensor heads with performances required for detecting the magnetic signals while enabling the magnetic sensor heads to be placed closer to the cellular tissue serving as the detection object in a distance required for realizing a desired spatial resolution.

Preferably, the cellular tissue magnetic signal detecting device includes the stimulus applying section for administrating at least one of the mechanical stimulus, the electromagnetic stimulus, heat and drug to the cellular tissue. Thus, the stimulus applying section administers at least one of the mechanical stimulus, the electromagnetic stimulus, heat and drug such that the cellular tissue magnetic signal detecting device can detect the magnetic signals resulting from the action of the cellular tissue due to the presence of stimulus administered by the stimulus applying section.

Preferably, the cellular tissue magnetic signal detecting device includes the cellular tissue sustaining section operative to supply the physiological extracellular fluid, having the ion composition osmotic pressure, to the cellular tissue at temperatures ranging from 0° C. to 42° C. so as to sustain the cellular tissue in the viability status. Thus, the cellular tissue sustaining section supplies the physiological extracellular fluid, having the ion composition osmotic pressure, to the cellular tissue at the temperatures ranging from 0° C. to 42° C., such that the cellular tissue magnetic signal detecting device can detect the magnetic signal generated by the cellular tissue remained in the viability status.

### BRIEF DESCRIPTION OF THE DRAWINGS

FIG. 1 is a view illustrating potential activities of cellular tissues including various living cellular tissues in a normal state.

FIG. 2 is a view illustrating various cellular tissues simultaneously growing up from a human iPS cell.

FIG. 3 is a view illustrating an outline of a technology of detecting an activity potential of a cellular tissue using a minute electrode provided on an experimental bath at a bottom surface thereof.

FIG. 4 is a view illustrating an outline of a technology of detecting a variation in activity potential of the cellular tissue upon utilizing a membrane voltage-sensitive dye.

FIG. 5 is a view illustrating an outline of a technology of detecting a magnetic signal of the cellular tissue upon utilizing a SQUID sensor.

FIG. 6 is a view illustrating an outline of a structure of a SQUID device used in a technique in FIG. 5.

FIG. 7 is a view representing one example of a detection result obtained upon detecting a magnetic signal generated by a cardiac muscle culture cell tissue by utilizing the SQUID sensor.

FIG. 8 is a view illustrating an outline of a device of one example of a cellular tissue magnetic signal detecting device according to the present invention.

FIG. 9 is a view illustrating an outline of a structure of an experimental bath section in the cellular tissue magnetic signal detecting device shown in FIG. 8.

FIG. 10 is a view illustrating one example of operation of an experimental bath which is moved by a manipulator in the cellular tissue magnetic signal detecting device shown in FIG. 8.

FIG. 11 is a view illustrating one example of a structure of a magnetic sensor head in the cellular tissue magnetic signal detecting device shown in FIG. 8.

FIG. 12 is a view illustrating a positional relationship among the experimental bath, a first magnetic sensor head and a second magnetic sensor head in the cellular tissue magnetic signal detecting device shown in FIG. 8.

FIG. 13 is a view illustrating an outline of a function of a computer provided in the cellular tissue magnetic signal detecting device shown in FIG. 8.

FIG. 14 is a view representing a time change in a spontaneous magnetic fluctuation of a smooth muscle cellular tissue specimen obtained by the cellular tissue magnetic signal detecting device shown in FIG. 8.

FIG. 15 is a view, representing a time change in the spontaneous magnetic fluctuation of the same smooth muscle cellular tissue specimen as that of FIG. 14, which represents a result of a temperature different from that shown in FIG. 14.

FIG. 16 is a view obtained by making a comparison between the time changes in the spontaneous magnetic fluctuation before and after a drug is administered onto the smooth muscle cellular tissue specimen in terms of a frequency spectrum.

FIG. 17 is a view obtained by making a comparison between a time change in the spontaneous magnetic fluctuation and a time change in an extracellular potential fluctuation for the same smooth muscle cellular tissue specimen.

FIG. 18 is a view illustrating a experimental example in which the cellular tissue magnetic signal detecting device of the present invention detects the presence of or absence of induction of a nerve cell in an intestinal tract cellular tissue induced from an ES cell.

FIG. 19 is a view representing another embodiment of the cellular tissue magnetic signal detecting device according to the present invention and illustrating an amorphous element having a different shape comprised in a magnetic sensor head.

FIG. 20 is a view representing another embodiment of the cellular tissue magnetic signal detecting device according to the present invention and illustrating the amorphous element having the different shape comprised in the magnetic sensor head.

FIG. 21 is a view illustrating an application of the cellular tissue magnetic signal detecting device according to the present invention and illustrating a myocardial sheet in the experimental bath.

FIG. 22 is a view illustrating another application of the cellular tissue magnetic signal detecting device according to the present invention and illustrating exemplary cellular tissues of plural kinds in the experimental bath.

FIG. 23 is a view illustrating another embodiment of the experimental bath for the cellular tissue magnetic signal detecting device according to the present invention.

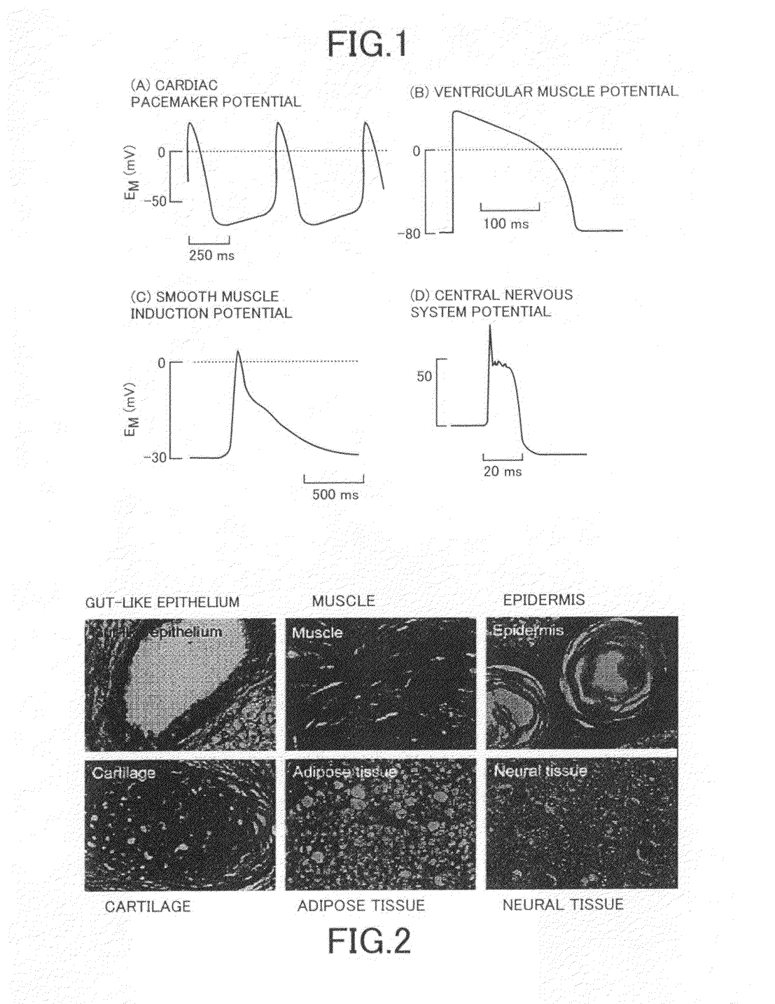

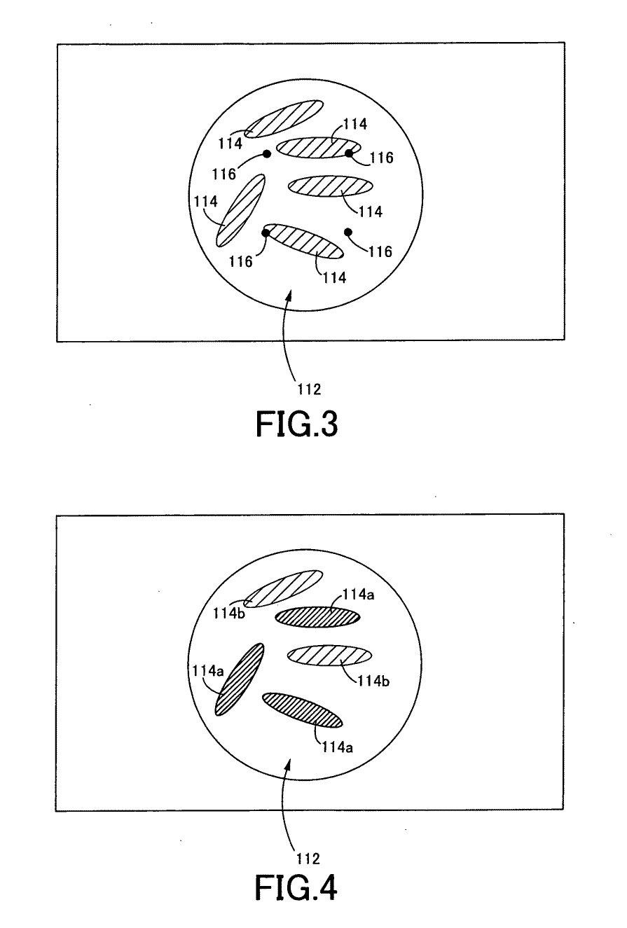

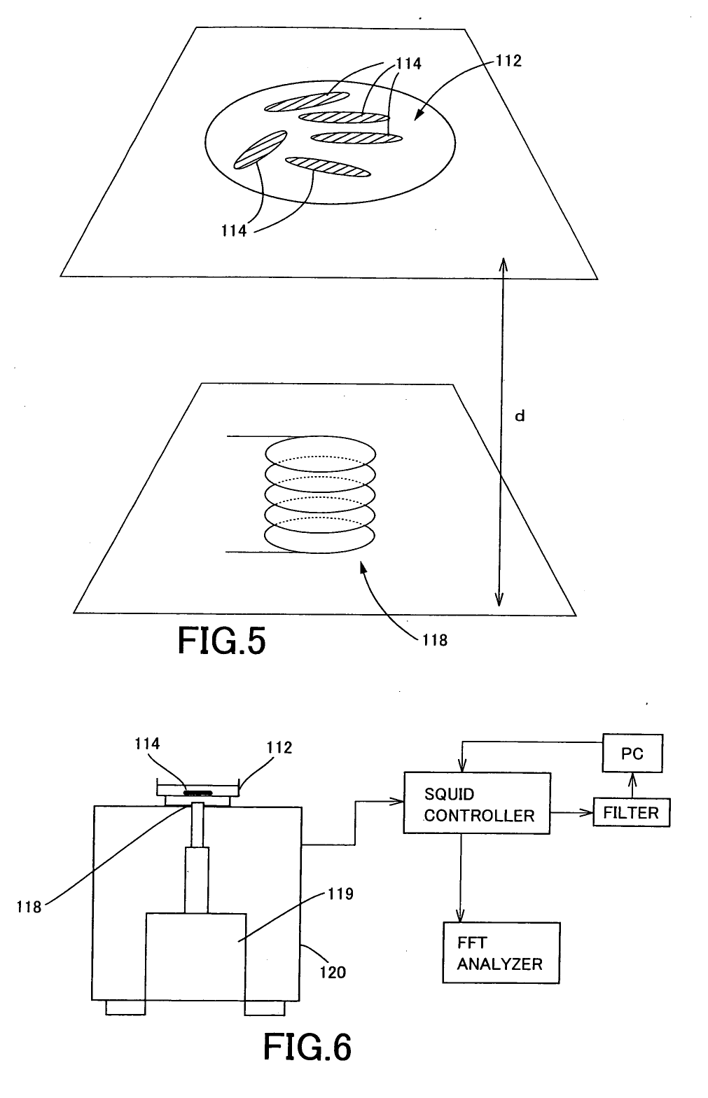

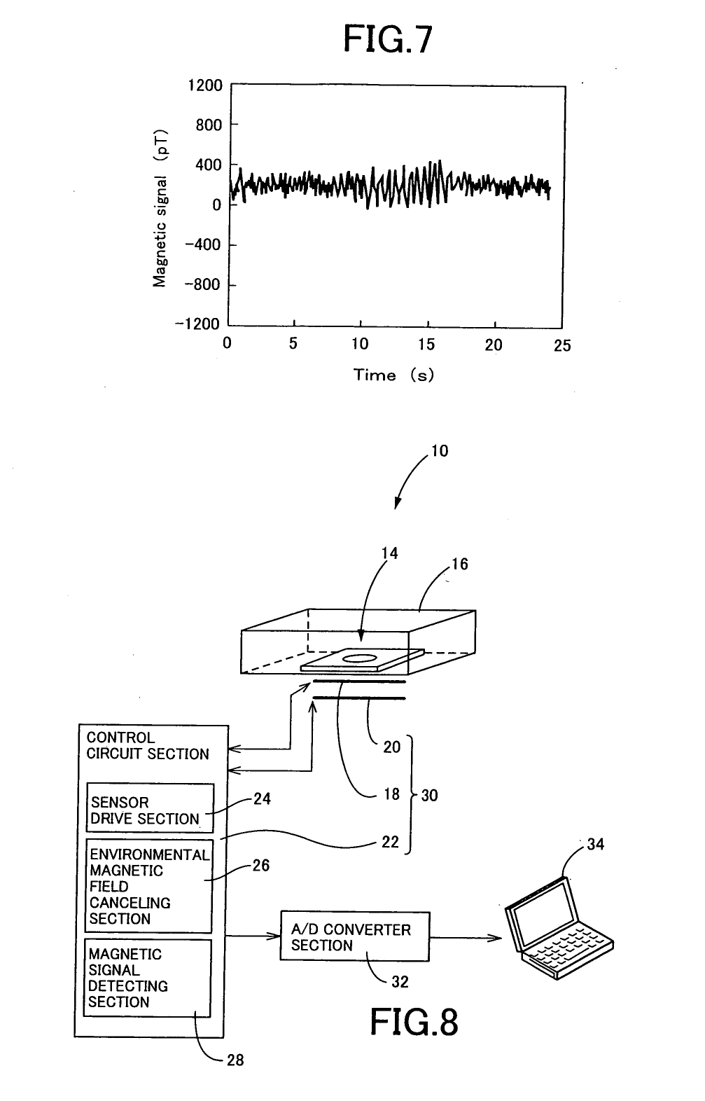

### NOMENCLATURE OF ELEMENTS

10: Cellular tissue magnetic signal detecting device
18, 20: Magnetic sensor heads
18: First magnetic sensor head
20: Second magnetic sensor head
26: Environmental magnetic field canceling section
30: Magnetic detecting section
50: Cellular tissue
70: Cellular tissue sustaining section
76: Stimulus applying section
84: Amorphous wires (Columnar magnetic bodies)
88: Tabular or thin film-like magnetic bodies
90A, 90B: Magnetic bodies having mesh-like structure

### BEST MODE FOR CARRYING OUT THE INVENTION

Now, embodiments of the present invention will be described below in detail with reference to the accompanying drawings.

### Embodiment 1

FIG. 8 is a view illustrating an outline of a structure of a cellular tissue magnetic signal detecting device 10 of one embodiment according to the present invention. As shown in FIG. 8, the cellular tissue magnetic signal detecting device 10 includes an experimental bath section 14, two magnetic sensor heads in the form of a first magnetic sensor head 18 and a second magnetic sensor head 20, and a control circuit section 22, etc. Further, the control circuit section 22 outputs a detection result in the form of a magnetic signal, which is subjected to processing in digital conversion with, for instance, an A/D converter section 32 shown in FIG. 8 to be recorded in a computer 34 used for data collection or the like.

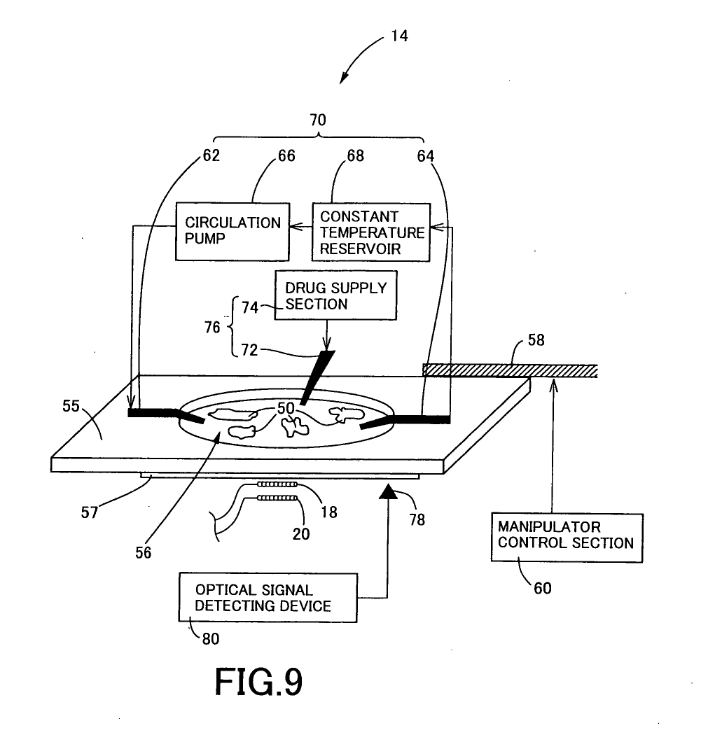

Among these, the experimental bath section 14 includes an experimental bath 56 in which cellular tissues 50 are located as detection objects. FIG. 9 is a view for illustrating a structure of such an experimental bath section 14 in detail. The experimental bath 56 includes a plate-like silicone (silicone plate) 55, through which a hole cylindrically extends, and a cover glass 57 attached to the silicone plate 55 on a lower side thereof in an overlapping fashion. Thickness of the cover glass 57 is 100 μm for example. That is, the experimental bath 56 takes the form of a cylindrical vessel with the cover glass 57 serving as a bottom while the hole, cylindrically extending through the silicone plate 55, serves as a wall surface.

Furthermore, the silicone plate 55 is fixedly secured to a manipulator 58 such that the silicone plate 55, i.e., the experimental bath 56 formed in the silicone plate 55, moves in conjunction with the movement of the manipulator 58. The manipulator 58 is made movable in, for instance, a planar direction of the silicone plate 55 in response to a control signal delivered from a manipulator control section 60.

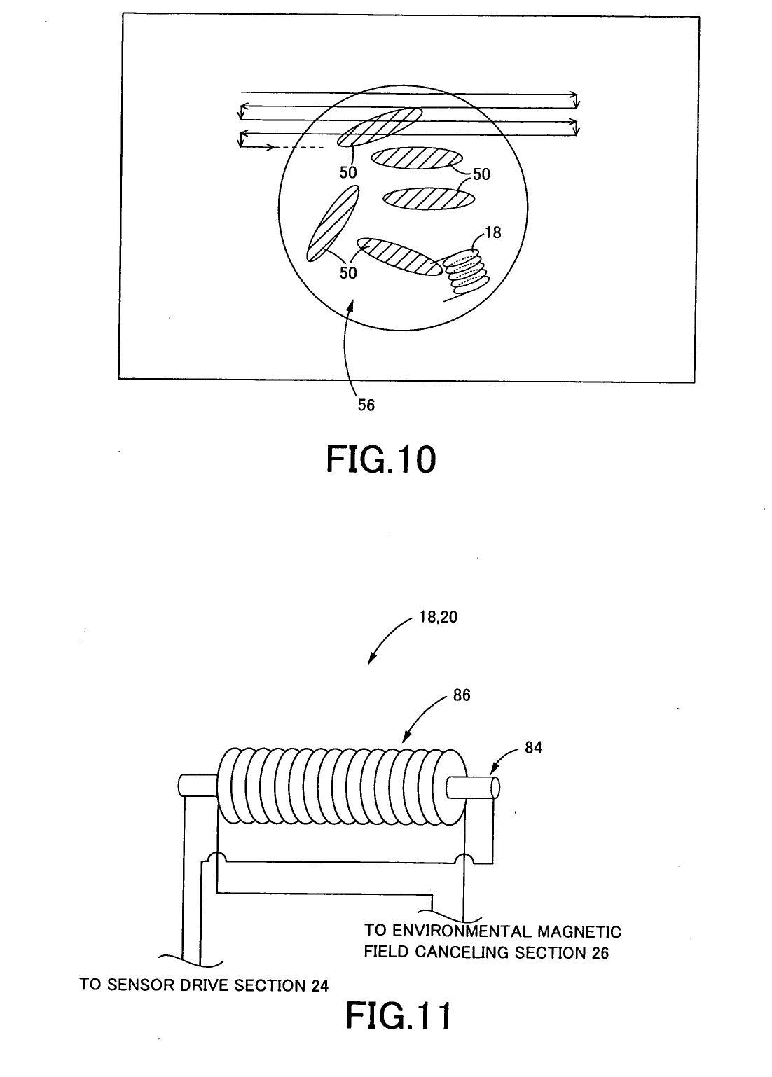

FIG. 10 is a view illustrating one example of movements of the experimental bath 56 that is moved by the manipulator 58. As a result of causing the experimental bath 56 to move in a manner as indicated by arrows in FIG. 10, the first magnetic sensor head 18 (described later), fixedly provided below the experimental bath 56 in an area covering an entire part of the experimental bath 56, can detect the resulting magnetic signal. In addition, when desired to detect a magnetic signal on a specified area of the experimental bath 56, it may suffice to control operation of the manipulator 58 such that the specified area is positioned above the first magnetic sensor head 18.

Turning back to FIG. 9, with a view to sustaining the cellular tissue in a viability state (living state), the experimental bath 56 is supplied with a physiological extracellular fluid having an ion-composition osmotic pressure at a predetermined temperature within temperatures ranging from 0° C. to 42° C. The physiological extracellular fluid (perfusion liquid) is supplied from a perfusion liquid inlet tube 62 into the experimental bath 56. Moreover, a circulation pump 66 sucks the physiological extracellular fluid from the experimental bath 56 via a perfusion-liquid suction tube 64 such that the physiological extracellular fluid is circulated through the perfusion liquid inlet tube 62 for supply to the experimental bath 56. In addition, a constant temperature reservoir 68 is disposed in a circulating route of the physiological extracellular fluid such that the physiological extracellular fluid, sucked by the perfusion-liquid suction tube 64, is heated or cooled by the constant temperature reservoir 68 at the predetermined temperature mentioned above. With an excitable cellular tissue serving as the object to be detected by the cellular tissue magnetic signal detecting device 10 of the present invention, an electric activity is created by an ion flow resulting from activating ion transporter. Therefore, no ion flows at 0° C. or less at which water inside or outside a cell is solid. At 42° C. or more, the cell is injured in function due to the formation of heat shock protein, resulting in the occurrence of irreversible change. Therefore, the temperature of the physiological extracellular fluid lies at the predetermined temperature ranging from 0° C. to 42° C. to sustain the cellular tissue in the viability state for keeping homeostasis. These structures for circulation of the physiological extracellular fluid, i.e., the perfusion liquid inlet tube 62, the perfusion-liquid suction tube 64, the circulation pump 66 and the constant temperature reservoir 68 correspond to a cellular tissue sustaining section 70.

A stimulus applying section 76 serves to apply a stimulus onto the cellular tissues 50 placed inside the experimental bath 56 and is shown as including a drug supply section 74 and a pipette 72 in the illustrated embodiment. The pipette 72, caused to move by a manipulator, not shown, or fixedly provided in a predetermined position allows the drug to fall in drop onto an arbitrary position in the experimental bath 56 when the experimental bath 56 is moved by the manipulator 58. Causing the drug, supplied from the drug supply section 74, to fall in drop in a shifted position allows the drug to be administered as one form of stimulus onto an arbitrary part of the cellular tissue 50 placed in the experimental bath 56. The drug supply section 74 preliminarily stores therein the drug capable of stimulating an excitable cellular tissue, serving as an object to be detected by the cellular tissue magnetic signal detecting device 10, for supplying the pipette 72 with a predetermined amount of the drug.

Further, an optical sensor 78 and an optical signal detecting device 80 are of the types that are employed in another embodiment and, hence, relevant description will be made later.

Turning back to FIG. 8, the experimental bath section 14 has a circumference covered with a vessel 16 made of, for instance, plastic such that the experimental bath 56 and a surrounding temperature (environmental temperature) of the cellular tissue 50, placed in the experimental bath 56, are kept under desired temperatures. In addition, the vessel 16 is made of a substance having no magnetic shield (screening). Moreover, the vessel 16 may preferably include a transparent vessel to allow a light beam to be irradiated from the outside and to allow an optical sensor, located outside, to detect the occurrence of fluorescence in the interior.

Both of the first magnetic sensor head 18 and the second magnetic sensor head 20 serve as the sensors for detecting magnetic signals and may include, for instance, ultrasensitive MI (Magneto Impedance) sensors, respectively. FIG. 11 is a view illustrating one example of structures of the first magnetic sensor head 18 and the second magnetic sensor head 20 (hereinafter referred to as “magnetic sensor heads 18 and 20” unless otherwise distinguished from each other). As shown in FIG. 11, the magnetic sensor heads 18 and 20 include amorphous wires 84 in the form of columnar magnetic material bodies, and detection coils 86 concentrically wound on the amorphous wires 84, respectively. A high frequency alternating current, generated by a sensor drive section 24 which is described later (see FIG. 8), is applied across the both ends of each amorphous wire 84 at a level of, for instance, 30 kHz or more. Then, a magnetic flux, occurring in the amorphous wire 84, causes the detection coil 86 to create a voltage, which is detected by the magnetic signal detecting section 28 which is described later. Here, when a high frequency current is applied through the amorphous wire 84, if an external magnetic field applied with a magnetic flux density per unit surface area lying in the order of, for instance, 0.2 nT to 1 nT, then, impedance across both ends thereof remarkably varies due to a magnetic impedance effect. Accordingly, detecting the voltage across the both ends of the detection coil 86 while detecting the variation in impedance of the amorphous wire 84 based on the voltage being detected results in a capability detecting a variation in outside magnetic field applied to the amorphous wire 84.

Further, the magnetic sensor heads 18 and 20 are arranged to operate within environmental temperatures ranging from 0° C. to 42° C. set up by the cellular tissue sustaining section 70 for ensuring a function of the living cellular tissue.

Further, the magnetic sensor heads 18 and 20 are arranged to have response speeds of lms or less in terms of a magnetic fluctuation. This is based on durations of activity potentials generated by various electrically excitable cells such as nerves, muscles and endocrine cells, etc., present in a living body. That is, even nerve cells, having the shortest activity potential duration, have activity potential duration ranging from 0.4 to 2 ms (see Non-Patent Publication 9 mentioned above). Therefore, if the response speed relative to the magnetic fluctuation, i.e., the response time when the cell responds to the magnetic fluctuation lies in about 1 ms or less, then, not only activities of nerve cells of a large number of kinds can be measured for evaluation but also activities of the various electrically excitable cells such as the muscles and the endocrine cells, etc., can be measured for evaluation.

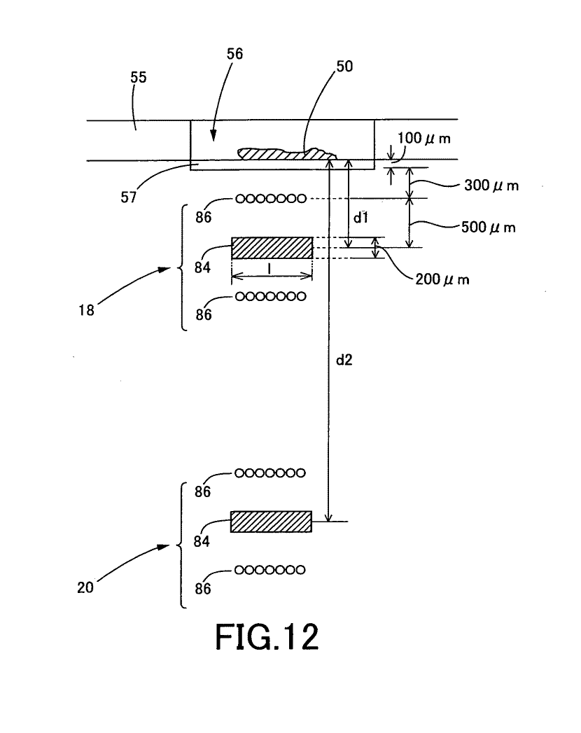

FIG. 12 is a view illustrating structures of the experimental bath 56, the first magnetic sensor head 18 and the second magnetic sensor head 20 and relative positions of the first magnetic sensor head 18 and the second magnetic sensor head 20. The first magnetic sensor head 18 and the second magnetic sensor head 20 include the columnar amorphous wires 84 and the detection coils 86 concentrically wound on the amorphous wires 84 in a columnar shape as stated above, respectively. More particularly, with the present embodiment, as shown in FIG. 12, the amorphous wires 84 of the first magnetic sensor head 18 and the second magnetic sensor head 20 have diameters of about 200 μm in a cross-sectional direction and the detection coils 86 have radii of about 500 μm in the cross-sectional direction. In addition, a space between the amorphous wire 84 and the detection coil may be hollow or filled with insulation material. Here, a length “d” of the amorphous wires 84 of the magnetic sensor heads 18 and 20 is set up to be a distance “11” or less between the cell and the first magnetic sensor head 18. With such setup, a magnetic field is created with a magnitude inversely proportional to the distance due to Ampere's law when causing the flow of electric current. Thus, a high spatial resolution can be obtained in the order of the distance “d1” between the cell and the first magnetic sensor head 18, i.e., a resolution of, for instance, 1000 μm. In addition, the magnetic sensor heads 18 and 20 are arranged such that a shape and size of the amorphous wires 84 and a shape, size and the number of turns, etc., of the detection coils 86 are set up to allow the magnetic signals, generated by the cellular tissues 50, to be measured at a noise level of 1 nT or less.

As shown in FIG. 12, further, the first magnetic sensor head 18 and the second magnetic sensor head 20 are positioned below the experimental bath 56 along a common vertical axis to allow both components to lay in parallel to each other. For instance, the amorphous wires 84 of the first magnetic sensor head 18 and the second magnetic sensor head 20 are positioned to have axes extending parallel to each other. In the present embodiment, the first magnetic sensor head 18 and the second magnetic sensor head 20 are held by sensor head holders or the like, not shown, such that the axial directions of both the amorphous wires 84 of the first magnetic sensor head 18 and the second magnetic sensor head 20 extend in parallel to the bottom of the experimental bath 56, i.e., in a way to be horizontal. The distance “d1” between the first magnetic sensor head 18 and the cellular tissue 50 is selected to be shorter than a distance “d2” between the second magnetic sensor head 20 and the cellular tissue 50, i.e., in FIG. 12, the second magnetic sensor head 20 is positioned below the first magnetic sensor head 18. Moreover, the distance “d1” between the first magnetic sensor head 18 and the cellular tissue 50 is defined as a distance between a center of an area at which the first magnetic sensor head 18 detects the magnetic field and a lower surface of the cellular tissue 50. That is, as shown FIG. 12 for the present embodiment, if the first magnetic sensor head 18 includes the columnar amorphous wire 84 whose axis is parallel to the bottom of the experimental bath 56, then, the distance is defined to be a distance between the axis of the amorphous wire 84 and the bottom of the experimental bath 56, i.e., the lower surface of the cellular tissue 50. The distance between the magnetic sensor head and the cellular tissue is similarly defined for the second magnetic sensor head 20 or a magnetic sensor head in another embodiment.

Here, the distance “d1” between the first magnetic sensor head 18 and the cellular tissue 50 is considered a distance capable of detecting the magnetic field generated by the cellular tissue 50 and, more particularly, considered to be, for instance, 1 mm or less. Meanwhile, the distance “d2” between the second magnetic sensor head 20 and the cellular tissue 50 may suffice for a difference magnitude between a detection signal resulting from the first magnetic sensor heads 18 and a detection signal resulting from the second magnetic sensor head 20, to be calculated by an environmental magnetic field canceling section 26, described below, to lay in a distance that can exceed a noise level of a magnetic detecting section 30 which will be described below. In particular, for instance, the magnetic field, generated by the cellular tissue 50, may be detected only by the first magnetic sensor head 18, whereas the magnetic field around the experimental bath 56, i.e., an environmental magnetic field, may suffice to be detected by both of the first magnetic sensor head 18 and the second magnetic sensor head 20. In FIG. 12, the cover glass 57, placed on the silicone plate 50 as the bottom of the experimental bath 56, has a thickness of 100 μm and the first magnetic sensor head 18 is located to allow the distance between an upper end of the detection coil 86 and the lower surface of the cover glass 57 to be 300 μm. In addition, as set forth above, since the radius of the detection coil 86 in the cross section thereof is 500 μm, the distance “d1” between the first magnetic sensor head 18 and the cellular tissue 50 is set to be 900 μm falling below 1 mm representing the distance capable of detecting the magnetic field generated by the cellular tissue 50.

Further, the magnetic sensor heads 18 and 20 have noise levels with allowances determined based on the magnitude of the magnetic field, i.e., the magnetic flux density, generated by the cellular tissue 50 serving as the detection object. For instance, in a case where the magnetic fluctuation, occurring along with the activity potential of the cellular tissue 50, has an amplitude laying in a range of approximately 500 to 1000 pT, the magnetic sensor heads can be used for the purpose of evaluating the functioning of the cellular tissue 50 provided that the noise levels of the magnetic sensor heads 18 and 20 (especially the first magnetic sensor head 18), enabled to approach the cellular tissue 50 within 1000 μm therefrom, is 1000 pT or less.

Turning back to FIG. 8, the control circuit section 22 drives the magnetic sensor heads 18 and 20, while retrieving the signals detected by the magnetic sensor heads 18 and 20, and extracts only a signal associated with the magnetic field (magnetic signal) resulting from the cellular tissue 50 by predetermined procedure. The control circuit section 22, formed of, for instance, an analogue circuit, functionally includes the censor drive section 24, the environmental magnetic field canceling section 26 and the magnetic signal detecting section 28.

The sensor drive section 24 generates an alternating current at a high frequency to energize (pass through) the respective amorphous wires 84 of the first magnetic sensor head 18 and the second magnetic sensor head 20. The high frequency alternating current has the frequency and electric current whose values are determined to enable the amorphous wires 84 of the first magnetic sensor head 18 and the second magnetic sensor head 20 to create magnetic impedance phenomena. In the present embodiment, as described in the Non-Patent Publication 10, for instance, the sensor drive section 24 utilizes a CMOS-inverter incorporated IC as a timer circuit to generate pulses at 33 μs intervals. Therefore, the amorphous wires 84 may generate the magnetic impedance phenomena and the response time to the magnetic fluctuation can be 33 μs in the shortest, causing the activity of the cellular tissue 50 to be adequately measured.

The environmental magnetic field canceling section 26 eliminates the influence of an environmental magnetic field based on a voltage detected by the detection coil 86 of the first magnetic sensor head 18 and a voltage detected by the detection coil 86 of the second magnetic sensor head 20. In the present embodiment, as set forth above, the first magnetic sensor head 18 and the second magnetic sensor head 20 are arranged in such a way to allow the magnetic field, generated by the cellular tissue 50, to be detected only by the first magnetic sensor head 18 while allowing the detection of the environmental magnetic field by both of the first magnetic sensor head 18 and the second magnetic sensor head 20. Accordingly, subtracting the voltage, detected by the detection coil 86 of the second magnetic sensor head 18, from the voltage detected by the detection coil 86 of the first magnetic sensor head 18 results in a capability of eliminating the influence of the environmental magnetic field. When this takes place, the distance “d1” between the first magnetic sensor head 18 and the cellular tissue 50 is set to be the distance enabled to detect the magnetic field generated by the cellular tissue 50. The distance “d2” between the second magnetic sensor head 20 and the cellular tissue 50 is set to be a distance in which the magnitude in difference between the detection signal resulting from the first magnetic sensor head 18 and the detection signal resulting from the second magnetic sensor head 20, both of which are calculated by the environmental magnetic field canceling section 26 described later, can exceed a noise level of the magnetic detecting section 30 that will be described later. This makes it possible to detect a voltage associated with the magnetic field generated by the cellular tissue 50 based on the difference between the voltages detected by the detection coils 86 of the first magnetic sensor head 18 and the second magnetic sensor head 18.

The magnetic signal detecting section 28 calculates the magnitude of the magnetic field generated by the cellular tissue 50 in terms of, for instance, a magnetic flux density or the like based on the voltage, associated with the magnetic field generated by the cellular tissue 50, which is calculated by the environmental magnetic field canceling section 26 in such a way to eliminate the influence of the environmental magnetic field.

Thus, the first magnetic sensor head 18, the second magnetic sensor head 20 and the control circuit section 22 can obtain the magnitude (strength) of the magnetic field generated by the cellular tissue 50 and, hence, all of these component parts can be regarded to be the magnetic detecting section 30 as a whole.

The A/D converter section 32, comprised of an A/D converter of, for instance, 16 bits or 32 bits, etc., performs the processing of a time change in the magnitude of the magnetic field, generated by the cellular tissue 50 and calculated by the magnetic signal detecting section 28 of the control circuit section 22, in digital data to be input into a computer that will be described later. In addition, the A/D converter section 32 has a resolution, unlimited by the 16 bits or 32 bits or the like mentioned above, which may be suitably altered depending on the resolutions of the magnetic sensor heads 18 and 20.

The computer 34 includes a so-called microcomputer composed of, for instance, a CPU, a RAM, a ROM and input/output interfaces or the like with the CPU performing signal processing in accordance with programs preliminarily stored in the ROM while utilizing a temporary data storing function of the RAM. This results in processing of information on a change in magnetic field generated by the cellular tissue 50 to be output from the control circuit section 22 and processed by the A/D converter section 32 in digital data.

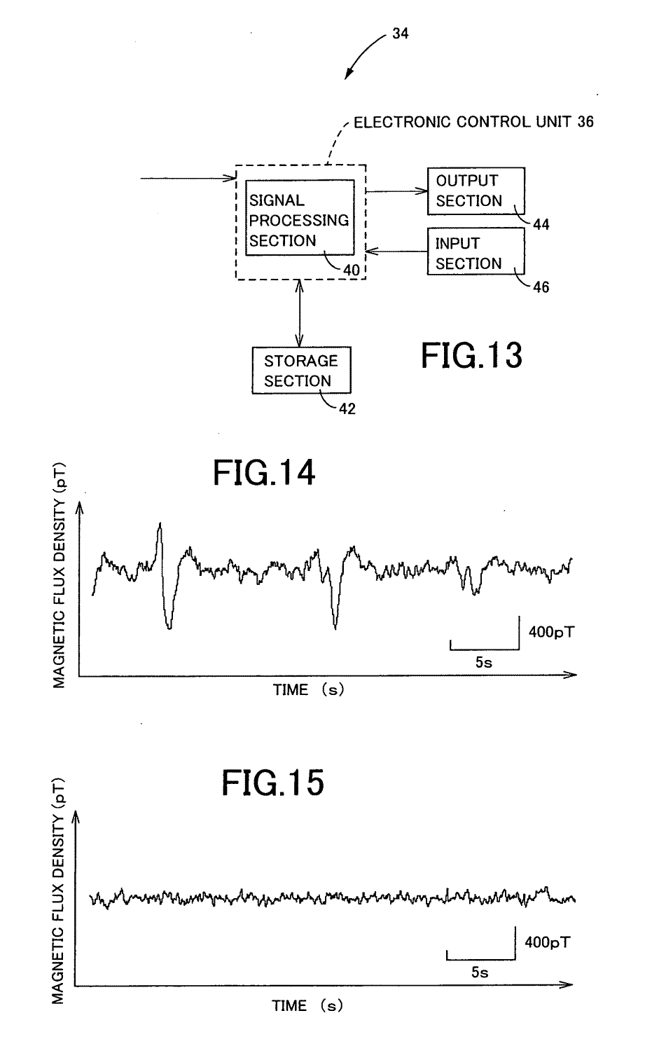

FIG. 13 is a functional block diagram illustrating one example of the functioning of the computer 34. An electronic control unit (CPU) 36 includes a signal processing section 40. The signal processing section 40 processes information on the change in the magnetic field, generated by the cellular tissue 50 to be output by the control circuit section 22 and processed by the A/D converter section 32 in digital data, in accordance with the preliminarily stored programs and outputs provided by an operator by means of an input section 46 such as a keyboard or the like. Moreover, depending on needs, the signal processing section 40 executes, for instance, FFT (Fast Fourier Transformation) and IFT (Inverse Fast Fourier Transformation) for an input signal in the form of information on the change in the magnetic field in order to execute filtering, that is, to emphasize or remove signal component in a specified range of frequency. For instance, information on the change in the magnetic field is stored in a storage section 42 such as a memory and a hard disc or the like. Alternatively, information on the change in the magnetic field is displayed as a change in passage of time on a display area of an output section 44 such as a display device or the like.

Hereunder, experimental examples conducted using the cellular tissue magnetic signal detecting device 10 of the present embodiment will be described below.

### Experimental Example 1

A smooth muscle cellular tissue specimen, taken out of a bladder of a marmot, was placed as the cellular tissue 50 in the experimental bath 56. The magnetic sensor heads 18 and 20 are placed below the cellular tissue 50 by operating the manipulator 58, and a localized magnetic fluctuation of the cellular tissue 50 was measured.

The constant temperature reservoir 68 of the cellular tissue sustaining section 70 was controlled and a liquid temperature of an extracellular fluid, supplied to the experimental bath 56, was adjusted to keep the liquid temperature of the extracellular fluid in the experimental bath 56 under a normal body temperature environment at about 37° C. Then, a diagram shown in FIG. 14 was obtained by the computer 34 representing the time change in the magnetic field generated by the cellular tissue 50. FIG. 14 represents a spontaneous magnetic fluctuation phenomenon. The spontaneous magnetic fluctuation occurred at amplitudes ranging from 500 to 1000 pT.

Meanwhile, as a temperature of the extracellular fluid in the experimental bath 56 was caused to drop to about 27° C., a result was obtained by the computer 34 in terms of the time change in the magnetic field generated by the cellular tissue 50 as indicated by a diagram shown in FIG. 15. This FIG. 15 represents that the spontaneous magnetic fluctuation in the cellular tissue 50 was discontinued.

Experimental Examples, shown in FIGS. 14 and 15, represent localized magnetic measurements continuously conducted using the same smooth muscle cellular tissue specimen. The smooth muscle cellular tissue specimen, used in the present Experimental Example, is well known to perform a spontaneous potential activity on temperature dependence. That is, as shown in FIG. 14 and FIG. 15, the present embodiment represents that the change in magnetic field by the occurrence of the spontaneous magnetic fluctuation and discontinuation of such occurrence accompanied were detected as the localized magnetic fluctuation occurring in the cellular tissue.

### Experimental Example 2

In Experimental Example 2, like Experimental Example 1 mentioned above, the smooth muscle cellular tissue specimen, representing one example of an excitable cellular tissue, was placed as the cellular tissue 50 in the experimental bath 56. The magnetic sensor heads 18 and 20 are placed below the cellular tissue 50 by operating the manipulator 58, while the liquid temperature of the extracellular fluid in the experimental bath 56 was kept under the normal body temperature environment at about 37° C. Then, the stimulus applying section 76 administered tetraethylammonium as a drug for activating electric excitation onto a part of the cellular tissue 50, located above the magnetic sensor heads 18 and 20, upon which localized magnetic fluctuations in the cellular tissue 50 before and after the administration were measured.

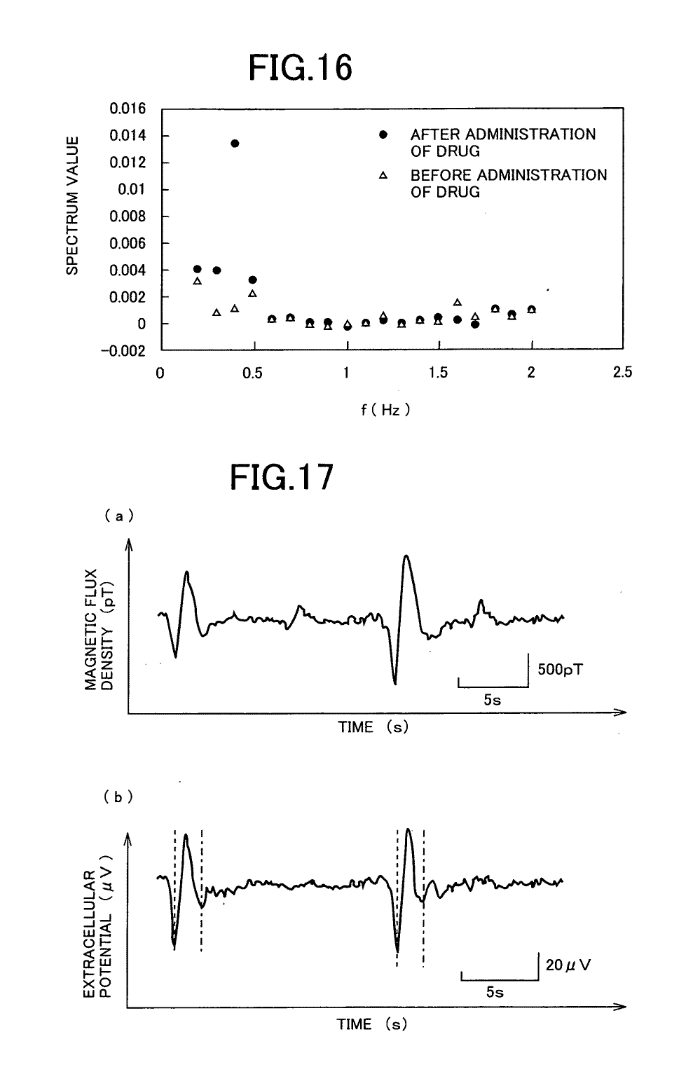

Before and after the administration of tetraethylammonium, time changes in magnetic fluctuations for respective predetermined times were detected and resulting waveforms were converted in terms of frequency spectrum for each 0.1 Hz with a result shown in FIG. 16. FIG. 16 represents the frequency spectrum before the administration of tetraethylammonium (drug) by triangle plots and the frequency spectrum after the administration of the drug by round plots.

Upon making a comparison between the respective frequency spectrums present before and after the administration of the drug, a frequency component was confirmed to have an increment in the vicinity of 0.4 Hz after the administration of the drug. This complies with the occurrence of an activated spontaneous excitation in the smooth muscle cellular tissue specimen.

The frequency component incremented by the above-mentioned administration of the drug, i.e., the frequency component around 0.4 Hz, matches a frequency range of a spontaneous electrical exciting activity of a smooth muscle cellular tissue specimen at a normal temperature described on a study (see Non-Patent Publication 8) or the like related to a spontaneous electric excitation of a smooth muscle cellular tissue specimen.

According to Experimental Example 2, as shown in FIG. 16, an effect of the drug administered to the cellular tissue can be accurately evaluated by performing frequency analysis of a waveform of the time change in magnetic fluctuation based on the magnetic signal, generated by the cellular tissue 50, which is detected by the cellular tissue magnetic signal detecting device 10 of the present embodiment.

### Experimental Example 3

In Experimental Example 3, like Experimental Example 1 mentioned above, the smooth muscle cellular tissue specimen, representing one example of the excitable cellular tissue, was placed as the cellular tissue 50 in the experimental bath 56. Operating the manipulator 58 caused the magnetic sensor heads 18 and 20 to be located below the cellular tissue 50, upon which the liquid temperature of the extracellular fluid in the experimental bath 56 was kept under the normal body temperature environment at about 37° C., upon which the localized magnetic fluctuation of the cellular tissue 50 was measured. Then, a diagram shown in FIG. 17 (a) was obtained by the computer 34 representing the time change in the magnetic field generated by the cellular tissue 50.

Meanwhile, under conditions of the same extracellular fluid composition and liquid temperature as those of a case where the time change in magnetic field shown in FIG. 17 (a) were measured, the spontaneous electric activity (extracellular potential fluctuation) of the smooth muscle cellular tissue specimen of the same kind was recorded using an extracellular electrode, resulting in the time change as shown in FIG. 17 (b). FIG. 17 represents views showing (a) the time change in magnetic field and (b) the time change in potential plotted on the horizontal axis in terms of time. In addition, the excitable cellular tissue is known to have a time change in intracellular potential that is close to a differential value of the time change of the extracellular potential.

According to Experimental Example 3, as shown in FIG. 17, a change in the magnetic field of the smooth muscle cellular tissue specimen, detected by the cellular tissue magnetic signal detecting device 10 implementing the present invention, and a change in the potential of the smooth muscle cellular tissue specimen detected in a technique of the related art have waveforms that are extremely similar in shape. In view of the fact that with the cellular tissue, the fluctuation occurs in the extracellular potential due to a localized ion flow generated by an ion transporter while simultaneously causing the magnetic fluctuation, it is understood that the cellular tissue magnetic signal detecting device 10 of the present invention is an appropriate apparatus for detecting the localized magnetic fluctuation of the cellular tissue including the excitable cell which generates the electric excitation.

### Experimental Example 4

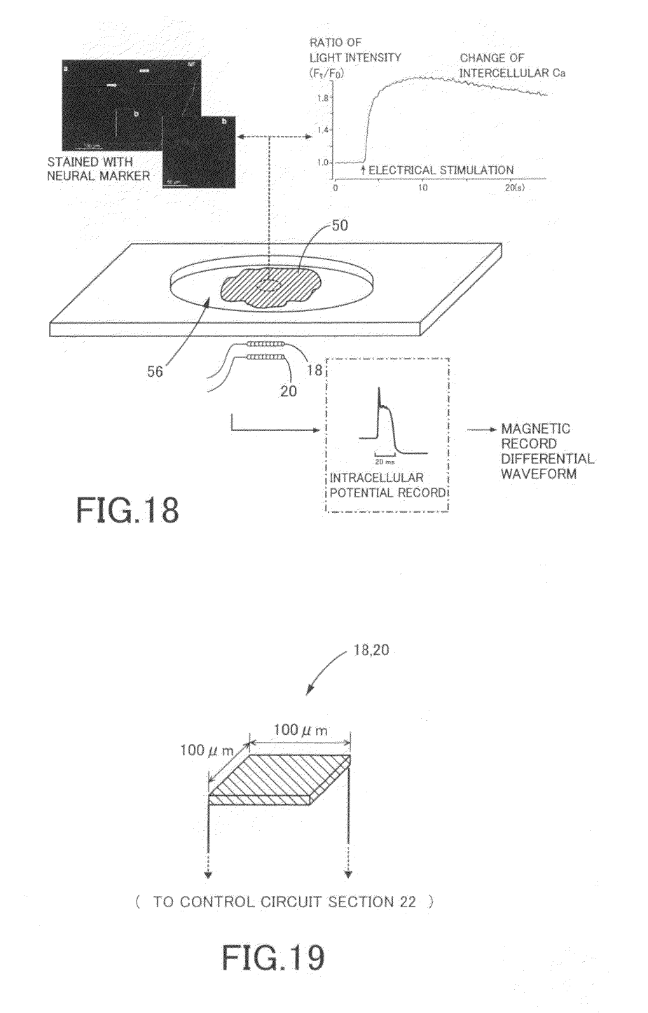

FIG. 18 is a view illustrating still another Experimental Example of the cellular tissue magnetic signal detecting device 10 of the present embodiment. In the present Experimental Example, a cellular tissue composed of an intestinal tract cellular tissue, induced from an ES cell, in which a nerve cell is further induced, was used as the cellular tissue 50 in detection object. Such a cellular tissue is disclosed in Non-Patent Publication 7 by the inventors of the present patent application. The presence of or absence of the nerve cell being induced in a specified area of the cellular tissue 50 in FIG. 18, i.e., an area surrounded by, for instance, a dotted line can be detected based on the localized magnetic fluctuation detected by the cellular tissue magnetic signal detecting device 10 of the present embodiment.

Meanwhile, as disclosed in Non-Patent Publication 7, using a Ca (calcium) sensitive optical probe enables to check the presence of or absence of the induced nerve cell inside the cellular tissue 50. More particularly, when electrical stimulation is performed stimulating the nerve cell, the observation of an increment in intracellular Ca at a specified area of the cellular tissue 50, i.e., at an area surrounded by, for instance, the dotted line in FIG. 18 results in an index of nerve cell induction. A graph placed at upper right of FIG. 18 represents a time change in concentration of the intracellular Ca before and after the electrical stimulation being conducted. The concentration of this intracellular Ca can be evaluated in terms of a ratio of a light intensity of the cellular tissue 50. The ratio of light intensity is expressed as a numeric value indicating an intensity of light being detected when the intensity of light is assigned to be “1” under a stationary condition, i.e., with no stimulation being conducted. In Non-Patent Publication 7, after an experimental test is conducted for measuring the concentration of intracellular Ca, the cellular tissue 50 is subjected to paraformaldehyde fixation upon which the cellular tissue 50 is further stained with a neural marker, thereby confirming that a group of nerve cells are induced. A photograph, appearing in FIG. 18 at the upper left thereof, represents an appearance in which the induced nerve cells are stained with the neural marker. Thus, Non-Patent Publication 7 discloses a technology of making determination on the presence of or absence of the nerve cells being induced based on the increase in the intracellular Ca.

However, when such a procedure is taken, a lot of trouble should be taken and, in addition, the cells should be fixed. Therefore, the cell, forming the cellular tissue, is subject to cell death. This results in a difficulty of continuously observing the growth of the nerve cells in subsequent step. Moreover, the Ca concentration varies at a slow varying speed and it becomes difficult to detect the variation responding to the potential generated in conjunction with each of nerve activities on a one-on-one basis.

As indicated in Experimental Example 4, meanwhile, the magnetic fluctuation of the cellular tissue, using in the cellular tissue magnetic signal detecting device 10 of the present embodiment, can be detected at a rate closer to the nerve intracellular potential as described above with reference to FIG. 17, i.e., has a response speed that is sufficiently fast. This makes it possible to make a determination on the presence of or absence of the induction of the nerve cells based on the result of detecting the magnetic fluctuation of the cellular tissue obtained by the cellular tissue magnetic signal detecting device 10.

With the present embodiment set forth above, the magnetic detecting section 30 includes the magnetic sensor heads 18 and 20 which can approach the cellular tissue within 1000 μm or less. And the magnetic detecting section 30 can detect the magnetic signals with a resolution of 1000 μm or less at a noise level of 1 nT or less with a response speed of 1 ms or less based on the output signals delivered from the magnetic sensor heads. Thus, the cellular tissue magnetic signal detecting device 10 of the present embodiment enables the locally generated magnetic signal to be detected based on the electric activity of the cellular tissue 50, including the excitable cell, in a contactless and noninvasive manner with respect to the cellular tissue 50 with a sufficient spatial resolution. Further, the magnetic signal, generated by a part of the cellular tissue, can be detected while identifying such a part.

With the present embodiment described above, further, the magnetic detecting section 30 includes the first magnetic sensor head 18 and the second magnetic sensor head 20 which is disposed to be longer in distance from the cellular tissue 50 than the distance between the cellular tissue 50 and the first magnetic sensor head 18. The magnetic detecting section 30 further includes the environmental magnetic field canceling section 26 for eliminating the influence of the environmental magnetic field based on the magnetic signals detected by the first magnetic sensor head 18 and the second magnetic sensor head 20. The environmental magnetic field canceling section 26 can eliminate the influence of the environmental magnetic field based on the magnetic signals detected by the first magnetic sensor head 18 and the second magnetic sensor head 20, respectively. Thus, in addition to the above-mentioned effects, the magnetic signal generated by the cellular tissue 50 with increased precision can be detected.

With the present embodiment noted above, furthermore, the magnetic sensor heads 18 and 20 include the amorphous wires 84 in the form of the columnar magnetic bodies. This allows the magnetic sensor heads to be provided with performances required for detecting the magnetic signals while permitting the magnetic sensor heads to be placed closer to the cellular tissue serving as the detection object in a distance needed for realizing a desired spatial resolution.

With the present embodiment mentioned above, moreover, the cellular tissue magnetic signal detecting device 10 includes the stimulus applying section 76 for administrating at least one of the mechanical stimulus, the electromagnetic stimulus, heat and drug to the cellular tissue 50. Thus, the stimulus applying section 76 administers at least one of the mechanical stimulus, the electromagnetic stimulus, heat and drug such that the cellular tissue magnetic signal detecting device 10 can detect the magnetic signals resulting from the action of the cellular tissue 50 due to the presence of stimulus administered by the stimulus applying section 76.

With the present embodiment mentioned above, besides, the cellular tissue magnetic signal detecting device 10 includes the cellular tissue sustaining section 70 operative to supply the physiological extracellular fluid, having the ion composition osmotic pressure, to the cellular tissue 50 at temperatures ranging from 0° C. to 42° C. so as to sustain the cellular tissue in the viability status. Thus, the cellular tissue sustaining section 70 supplies the physiological extracellular fluid, having the ion composition osmotic pressure, to the cellular tissue 50 at the temperatures ranging from 0° C. to 42° C., such that the cellular tissue magnetic signal detecting device 10 can detect the magnetic signal generated by the cellular tissue 50 remained in the viability status.

With the present embodiment described above, further, the cellular tissue magnetic signal detecting device 10 has no need to have equipment such as the liquid nitrogen vessel 119 or the like related to the cooling in contrast to the apparatus utilizing SQUID, thereby making it possible to be supplied at low cost while achieving the miniaturization.

Next, description will be made of another embodiment of the present invention. In the following description, the same reference numeral is given to component parts common to the embodiments to omit description.

### Embodiment 2

The present embodiment relates to structures of the magnetic sensor heads 18 and 20. In the previous embodiment, the magnetic sensor heads 18 and 20 are structured as shown in FIG. 11, i.e., in the structure including the columnar amorphous wires 84 and the cylindrical detection coils 86 concentrically wound on the amorphous wires 84, respectively. Then, the amorphous wires 84 are applied with the alternating current at the predetermined high frequency, and the voltage across the both ends of each detection coil 86 is detected. However, when the high frequency alternating current is applied to the amorphous wires 84, the magnetic impedance phenomena include phenomena in that impedances of the amorphous wires 84 per se vary depending on the variation in the magnetic fields around the amorphous wires 84. That is, the magnitudes of the magnetic fields around the amorphous wires 84 can be detected when impedances of the amorphous wires 84, i.e., values related to the impedances of the amorphous wires 84 on a one-on-one basis are detected.

Thus, in the present embodiment, the magnetic sensor heads 18 and 20 have no detection coils 86 in structure. The high frequency alternating current, generated by the sensor drive section 24 is passed through the amorphous wires 84, and the voltages across the both ends of the amorphous wires 84 are detected by the control circuit section 22. With such a structure, the signal processing section 22 can calculate the impedances of the amorphous wires 84 based on the voltages, appearing across the both ends of the amorphous wires being detected, and the magnitude of the high frequency alternating current generated by the sensor drive section 24.

With such an embodiment mentioned above, the magnetic sensor heads 18 and 20 can be structured with no provision of the detection coils, thereby enabling the amorphous wires 84 to be placed further closer to the cellular tissue 50 serving as the detection object. In general, the magnitude of the magnetic field decreases in proportion to the square of a distance and, thus, placing the magnetic sensor heads 18 and 20 to be closer to the cellular tissue 50 enables the cellular tissue magnetic signal detecting device 10 to have increased detecting precision.

### Embodiment 3

The present embodiment also relates to the structures of the magnetic sensor heads 18 and 20. As expressed in the previous embodiment, the magnetic sensor heads 18 and 20 can detect the magnitudes of the magnetic fields around the amorphous wires 84 with no need to provide the detection coils 86 when the impedances of the amorphous wires 84 or the values related to the impedances of the amorphous wires 84 on the one-on-one basis are detected.

In the present embodiment, like the Embodiment 2 set forth above, the magnetic sensor heads 18 and 20 do not include the detection coils 86. In the Embodiment 2 set forth above, meanwhile, the amorphous elements of the magnetic sensor heads 18 and 20 include the columnar amorphous wires 84 and, in the present embodiment, tabular or thin film-like amorphous elements 88 are employed. These amorphous elements 88 may be formed in configurations, such as rectangles or the like as shown, for instance, in FIG. 19 (see Non-Patent Publication 11), in which electrodes, located at apexes in diagonal positions, are applied with the high frequency alternating current generated by the sensor drive section 24, and the control circuit section 22 detects a voltage across both ends of the amorphous element 88. With such a structure, the signal processing section 22 can calculate the impedance of the amorphous element 88 based on the voltage, appearing across the both ends of the amorphous wire to be detected, and the magnitude of the high frequency alternating current generated by the sensor drive section 24. The thin film-like amorphous element 88 used in the present embodiment may be formed in, for instance, a sputtered thin film.

With the present embodiment described above, the magnetic sensor heads 18 and 20 include the amorphous elements 88 made of the tabular magnetic body or the thin film-like magnetic body. That is, the magnetic sensor heads have larger surface area than those of the amorphous wires 84 of the previous embodiment, thus skin effect which occurs when the alternating current is passed through is increased. Consequently, the magnetic sensor heads 18 and 20 can be provided with performances required for the detection of the magnetic signals. In addition, the magnetic sensor heads can be placed closer to the cellular tissue 50 serving as the detection object in a distance required for realizing a desired spatial resolution.

### Embodiment 4

The present embodiment relates to the structures of the magnetic sensor heads 18 and 20 and, more particularly, to the structures of the magnetic sensor heads 18 and 20 having further increased spatial resolutions.

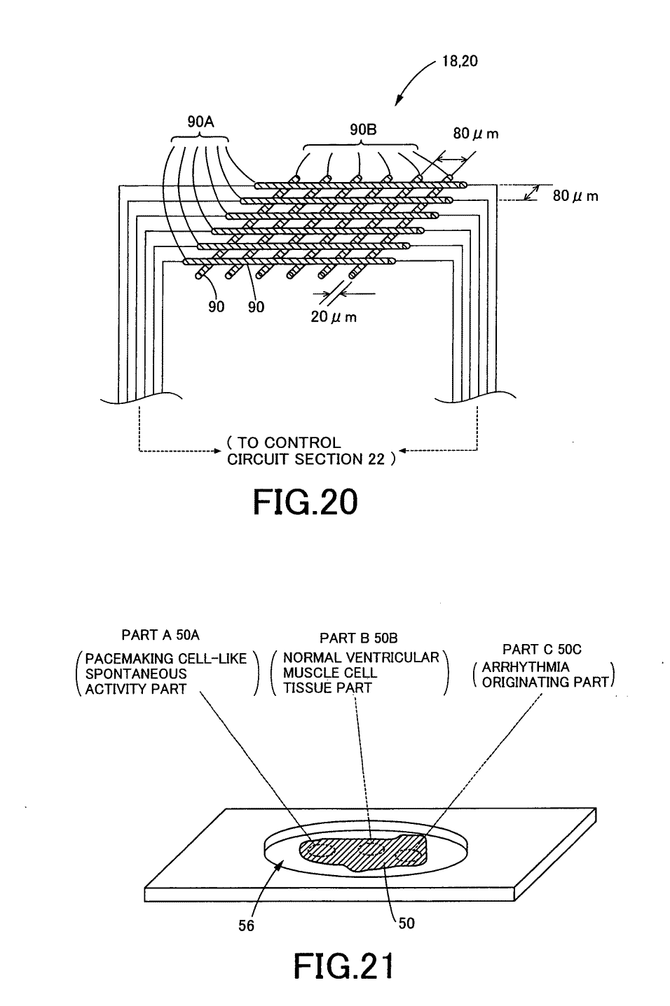

FIG. 20 is a view illustrating the structures of the magnetic sensor heads 18 and 20 of the present embodiment. As shown in FIG. 20, the magnetic sensor heads 18 and 20 are structured of magnetic bodies including amorphous wire sets 90A, each composed of a plurality of amorphous wires 90 placed parallel to each other at equidistant intervals, and amorphous wire sets 90B, each composed of a plurality of amorphous wires 90 placed parallel to each other at equidistant intervals so as to intersect the amorphous wires 90 composing the amorphous wire sets 90A at a certain angle. The magnetic bodies form mesh-like structure (lattice-like or matrix structure). With the present embodiment, as shown in FIG. 20, the amorphous wires 90, forming the amorphous wire sets 90A, and the amorphous wires 90, forming the amorphous wire sets 90B, are arranged to be mutually orthogonal, respectively.

The sensor drive section 24 allows the high frequency alternating current to be passed through the amorphous wires 90 forming the amorphous wire sets 90A and the amorphous wire sets 90B, respectively, such that the control circuit section 22 can detect voltages appearing across respective both ends of the amorphous wires 90. With such a structure, the signal processing section 22 can calculate impedances of the amorphous wires 84 based on the voltages appearing across the both end of the amorphous wires to be detected and the magnitude of the high frequency alternating current generated by the sensor drive section 24. FIG. 20 shows only a wire connecting example for the respective ones of the amorphous wires 90, forming the amorphous wire sets 90A, and the control circuit section 22 while omitting a wire connecting example for the respective ones of the amorphous wires 90, forming the amorphous wire sets 90B, and the control circuit section 22.

With such a structure, using either one of the amorphous wires 90, forming the amorphous wire sets 90A, and either one of the amorphous wires 90, forming the amorphous wire sets 90B, in combination with each other enables an intersection point between these amorphous wires to identify a position on the magnetic sensor heads 18 and 20 formed in the mesh-like structure. Thus, the magnetic sensor heads 18 and 20 of the present embodiment have further increased spatial resolutions. More particularly, in a case where, for instance, amorphous wires of 20 μm are placed at intervals of 80 μm as shown in FIG. 20, a spatial resolution of 100 μm can be obtained.

With the present embodiment set forth above, the magnetic sensor heads 18 and 20 include the magnetic bodies of the mesh-like structure, more particularly, the magnetic bodies formed of a plurality of the amorphous wires 90 arranged in the matrix configuration. This result in a capability of providing the magnetic sensor heads 18 and 20 with performances required for detecting the magnetic signals while enabling the magnetic sensor heads to be placed closer to the cellular tissue serving as the detection object in a distance required for realizing a desired spatial resolution.

While the present invention has been described above in detail with reference to the embodiments shown in the drawings, the present invention may be applied in other modes. The present invention may be implemented in combination with, for instance, the following applications described below.

(Application 1)

FIG. 21 is a view illustrating one of applications employing the cellular tissue magnetic signal detecting device 10 according to the present invention and showing the cellular tissue 50 placed in the experimental bath 56 of the cellular tissue magnetic signal detecting device 10. This Application 1 is to identify positions of cellular tissue parts of plural kinds partly present in one cellular tissue based on a magnetic signal generated by the cellular tissue for detection by the cellular tissue magnetic signal detecting device 10 of the present invention. In FIG. 21, the cellular tissue 50 includes a myocardial sheet in the form of one example of sheet-like cellular tissues formed of the master cell and the stem cell mentioned above. Cultured myocardial sheets do not necessarily have the same natures and the cultured myocardial sheets are likely to have a plurality of parts with different natures. In the cellular tissue 50 (myocardial sheet) shown in FIG. 19, for instance, three kinds of parts are shown including a part A (50A) in the form of a pacemaking cell-like spontaneous activity part, a part B (50B) in the form of a normal ventricular muscle cell tissue part, and a part C (50C) in the from of an arrhythmia originating part. When evaluating the cellular tissue having likelihood of the natures being individually different or having the parts in plural kinds of different natures, an evaluating technology with a spatial resolution is required.

The cellular tissue magnetic signal detecting device 10 of the present invention detects the localized magnetic fluctuations in an overall area of the myocardial sheet serving as the cellular tissue 50 placed in the experimental bath 56 for the predetermined intervals, determined based on the resolutions of the magnetic sensor heads 18 and 20, for preliminarily determined given time period respectively. The magnetic fluctuations being detected are input to the computer 34. Meanwhile, a sample pattern of the magnetic fluctuation which each part assumed to exist in the myocardial sheet would be generate is experimentally obtained in advance and stored in a storage section 42 (see FIG. 13) of the computer for each of the parts. Then, the signal processing section 40, functionally realized by the electronic control unit 36 of the computer, makes a comparison between respective one of the detected localized magnetic fluctuations generated by the cellular tissue 50 and the sample pattern stored in the storage section 42 using a known technique such as, for instance, pattern matching or the like. In a case where the localized magnetic fluctuation and the sample pattern are similar to each other in a range exceeding a predetermined degree of similarity, a determination is made that there is a part, corresponding to the sample pattern, in a position at which the localized magnetic fluctuation is detected. Repeatedly executing such processing results in a capability of identifying what is the part present in which position of the cellular tissue 50, more particularly, the distribution of the part A (50A), the part B (50B) and the part C (50C) present in the myocardial sheet serving as the cellular tissue 50.

With such processing, it becomes possible to identify what is the part present in which position of the cellular tissue 50, more particularly, the distribution of the part A (50A), the part B (50B) and the part C (50C) present in the myocardial sheet serving as the cellular tissue 50. This enables quantitative evaluation to be made based on the localized magnetic fluctuation of the cellular tissue 50 detected by the cellular tissue magnetic signal detecting device 10 of the present invention in respect of: how far the myocardial sheet, serving as the cellular tissue 50, is succeeded in differentiation induction to function as a myocardial cell (cardiomyocyte); or how much degree of the part C (part 50C: arrhythmia originating part), undesired as the myocardial sheet, is involved. In particular, with the present application, the cellular tissue 50 can be evaluated in the noninvasive manner. Thus, for instance, the cellular tissue 50 can be evaluated during a course of culturing the cellular tissue 50 (in life), and the culture can be continued after the evaluation.

(Application 2)

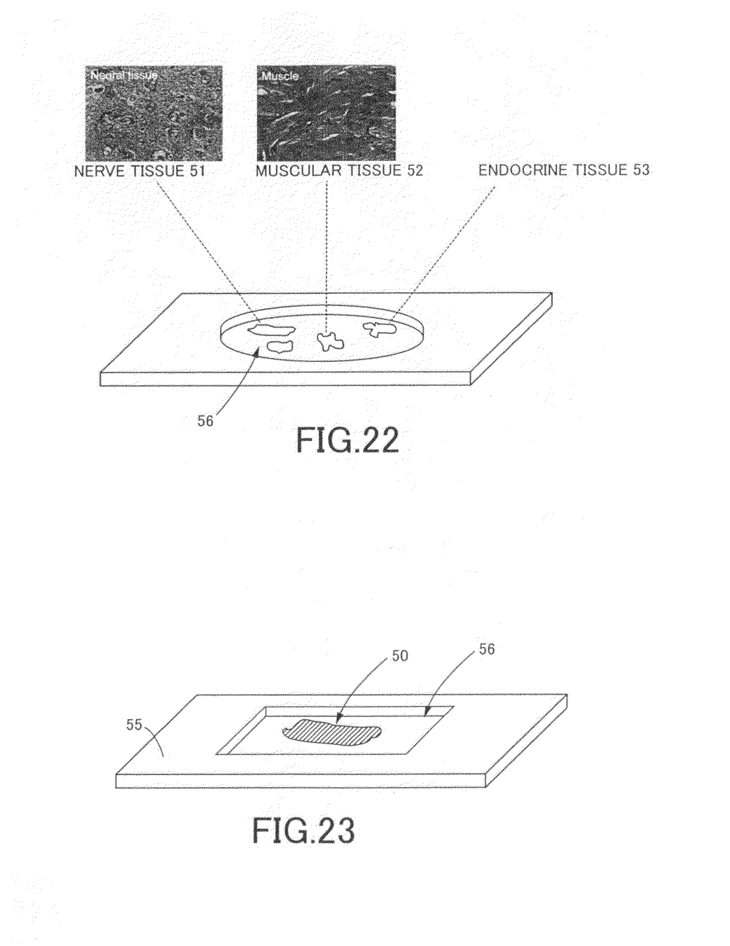

FIG. 22 is a view illustrating another application employing the cellular tissue magnetic signal detecting device 10 according to the present invention and showing plural kinds of cellular tissues 51, 52 and 53 placed in the experimental bath 56 of the cellular tissue magnetic signal detecting device 10. Application 2 is to identify the kinds of the cellular tissues 51 to 53 of the plural kinds based on magnetic signals generated by the cellular tissues 51 to 53 being detected by the cellular tissue magnetic signal detecting device 10 according to the present invention. In FIG. 22, the cellular tissues 51 to 53 represent the cellular tissues that grow as a result of culturing a master cell and a stem cell such as the iPS cell and the ES cell set forth above. In FIG. 22, for instance, the cellular tissue 51 is a nerve tissue; the cellular tissue 52 is a muscular tissue; and the cellular tissue 53 is an endocrine tissue. All of these tissues generate magnetic fluctuations different from each other.

Like Application 1 described above, the cellular tissue magnetic signal detecting device 10 of the present invention detects the localized magnetic fluctuations at the predetermined intervals, determined based on the resolutions of the magnetic sensor heads 18 and 20, for, for instance, the preliminarily determined given time periods for each of the cellular tissues 51 to 53 place in the experimental bath 56 respectively. The detected magnetic fluctuation is input to the computer 34. Meanwhile, a sample pattern of a magnetic fluctuation which would be generated by each cellular tissue is experimentally obtained in advance for each cellular tissue and is stored in the storage section 42 (see FIG. 13) of the computer. Then, the signal processing section 40, functionally realized by the electronic control unit 36 of the computer, makes a comparison between respective one of the detected localized magnetic fluctuations generated by either one of the cellular tissues 51 to 53 and the sample pattern stored in the storage section 42 using the known technique such as, for instance, pattern matching or the like. In a case where the localized magnetic fluctuation and the sample pattern are similar to each other in a degree exceeding a predetermined degree of similarity, a determination is made that the cellular tissue, located at a position in which the localized magnetic fluctuation is detected, is a cellular tissue corresponding to the sample pattern. Among the cellular tissues 51 to 53 placed in the experimental bath 56, the cellular tissues with the kinds being identified are processed, thereby enabling the cellular tissues to be classified.

With such processing, the cellular tissues 51 to 53, placed in the experimental bath 56, can be classified, respectively, on what kinds will be the cellular tissues. More particularly, in the example shown in FIG. 22, the classification may be made on whether the cellular tissue belongs to the nerve tissue, whether the cellular tissue belongs to the muscular tissue or whether the cellular tissue belongs to the endocrine tissue or the like. Thus, the cellular tissues, grew up due to the growth of the iPS cell and the ES cell or the like, can be classified based on the localized magnetic fluctuations of the cellular tissues detected by the cellular tissue magnetic signal detecting device 10 according to the present invention. In particular, since the present application allows the cellular tissues 51 to 53 to be evaluated in a noninvasive manner for instance, the cellular tissues 51 to 53 can be evaluated during a course of culturing the cellular tissues 51 to 53 (in life), and the culture can be continued after the evaluation.

In the embodiments mentioned above, further, although the sensor drive circuit 24 has been described as including the analogue circuit arranged to generate the high frequency alternating current at the predetermined frequency, the sensor drive circuit 24 may be comprised of an oscillating circuit such as a Colpitts oscillator or the like. As described in Non-Patent Publication 11, using, for instance, the Colpitts circuit enables the magnetic sensor heads 18 and 20 to have increased sensitivities.

With the embodiments set forth above, while the drug supply section 74 has been described as having the effect of supplying the drug into the experimental bath 56 via the pipette 72, this component part is not limited to such a structure. For instance, the drug may be mixed with the physiological extracellular fluid supplied from the cellular tissue sustaining section 70. In such a case, the cellular tissue sustaining section 70 may also function as the stimulus applying section 76.

With the embodiments set forth above, the stimulus applying section 76 has been described as including the drug supply section 74 for supplying the drug for acting on the cellular tissue 50 and the pipette 72 for causing the drug, supplied from the drug supply section 74, to fall in drops into the experimental bath 56. That is, although the stimulus, which the stimulus applying section 76 applies to the cellular tissue 50, has been the drug, the stimulus is not limited to a drug. In particular, the stimulus, which the stimulus applying section 76 applies to the cellular tissue 50, may include a mechanical stimulus, an electromagnetic wave, heat or the like and, in such a case, the stimulus applying section 76 is comprised of equipment associated with respective stimuli. For instance, if the stimulus, which the stimulus applying section 76 applies to the cellular tissue 50, is the mechanical stimulus, then, the stimulus applying section 76 may include a vibrating device or the like. In addition, if the stimulus, which the stimulus applying section 76 applies to the cellular tissue 50, is the electromagnetic wave, then, the stimulus applying section 76 may suffice to be an electrode or a magnetic pole. Moreover, if the stimulus, which the stimulus applying section 76 applies to the cellular tissue 50, is heat, then, the stimulus applying section 76 may include a cooling device or heating device which can locally cool or heat up. In place of applying the stimulus with the use of the stimulus applying section 76, in addition, gene transfer may be applied to a cell forming the cellular tissue 50 serving as the detection object. Thus, the magnetic field with a variation in magnitude, generated by the cellular tissue 50 upon introducing a gene of a protein such as, for instance, an ion channel or the like which is operative to generate an electric current or a gene having an action to control such a protein into the relevant cell, generates is detected. This result in a capability of detecting an effect of gene introduction mentioned above.

With the embodiments noted above, the experimental bath 56 of the cellular tissue magnetic signal detecting device 10 has been described as having the cellular tissue being located. However, the present invention is not limited to such arrangement and, for instance, a culture vessel of the cellular tissue per se can be employed as the experimental bath 56. By so doing, the magnetic signal can be detected for the detection object composed of the cellular tissue during the course of culture.

With the embodiments mentioned above, although the vessel 16 has been used for heat retention, the use of the vessel 16 is not limited to such a purpose. To speak more in detail, an environment control section may be provided for controlling environment inside the vessel, thereby enabling a variation in a constitution of air such as not only a temperature but also humidity or a carbon dioxide concentration, etc., of the vessel 16 for example. With such a structure, under a circumstance where the culture vessel for the cellular tissue is used as the experimental bath 56 as previously mentioned, it becomes possible to detect a localized magnetic fluctuation in the cellular tissue during a process in long-term culture even in different culture conditions of the cellular tissue.

With the embodiments mentioned above, the magnetic sensor heads 18 and 20 are provided below the experimental bath 56 with the cover glass 57 which is put between the magnetic sensor heads 18 and 20 and the experimental bath 56. However, the present invention is not limited to such arrangement and, for instance, the sensor heads 18 and 20 may be covered with thin films of which thickness is 100 μm or less respectively and may be put closely to the cellular tissue 50 from upper side of the experimental bath 56, and a localized magnetic fluctuation in the cellular tissue 50 can be detected.

The cellular tissue magnetic signal detecting device 10 may be arranged to include, in addition to the structure of the embodiments mentioned above, the optical sensor 78 and the optical signal detecting device 80 shown in FIG. 9. The optical sensor 78 and the optical signal detecting device 80 serve to form, for instance, a fluorescence optical microscope. Detecting a fluorescence yielded by the cellular tissue 50 present in the experimental bath 56 allows, for instance, operations to be performed simultaneously for detecting the localized magnetic signal in the cellular tissue 50 and for specifying a kind of a cell employing a fluorescence cell marker or the like. In addition, the optical sensor 78 may be disposed not only on the experimental bath 56 at the lower side thereof as shown in FIG. 9 but also on the experimental bath 56 at an upper side thereof.

With the embodiments set forth above, further, although the ultrasensitive MI magnetic sensors have been employed as the magnetic sensor heads 18 and 20, the present invention is not limited to such structures. That is, the magnetic sensor heads 18 and 20 are not limited to the MI sensors provided that the magnetic sensor heads 18 and 20 are feasible such that when the magnetic sensor heads come closer to the cellular tissue 50 serving as the detection object within 1000 μm, the magnetic signals are detected with a resolution of 1000 μm or less at a noise level of 1 nT or less with a response speed of 1 ms or less based on output signals delivered from the magnetic sensor heads.

With the embodiments set forth above, furthermore, the environmental magnetic field canceling section 26 and the magnetic signal detecting section 28, arranged to process the signals detected by the magnetic sensor heads 18 and 20, are provided in the control circuit section 22 composed of the analog circuit to allow the signals, processed by the control circuit section 22, to be processed by the A/D converter section 32 in digital data to be retrieved by the computer 34. However, the present invention is not limited to such embodiments. For instance, the signals, detected by the magnetic sensor heads 18 and 20, may be processed by the A/D converter section 32 in digital data, after which similar operation may be executed. In this case, the environmental magnetic field canceling section 26 and the magnetic signal detecting section 28 may be realized as a digital circuit that can be realized by, for instance, a computer or the like.

With the embodiments set forth above, moreover, although the experimental bath 56 has been formed in the cylindrical shape, the present invention is not limited to such a shape and may be formed in, for example, a rectangular shape as shown in FIG. 23 or another shape.

With the embodiments set forth above, besides, the distance “d1” between the first magnetic sensor head 18 and the cellular tissue 50 has been set up to fall in a value of approximately 1000 μm (see FIG. 12), the present invention is not limited to such embodiments. That is, the first magnetic sensor head 18 and the cellular tissue 50 are preferably located closer to each other for the purpose of detecting the magnetic signals with increased precision. For instance, the first magnetic sensor head 18 may be located to allow the upper end of the detection coil 86 of the first magnetic sensor head 18 and the lower surface of the cover glass 57 to be further closer to each other in FIG. 12.

With the embodiments set forth above, further, the cellular tissue magnetic signal detecting device 10 of the present invention has been arranged to be of the type detecting the magnetic signals, generated by the cellular tissue 50 including the excitable cell generating electrical excitation, but may be of the type detecting a magnetic signal generated by a single cell. That is, the detection object of the cellular tissue magnetic signal detecting device 10 is not limited to the cellular tissue 50 but may include a cell per se. More particularly, a nerve cell or the like of, for instance, a squid having a long axon may be selected to be the detection object.

With the embodiments set forth above, furthermore, although the magnetic sensor heads 18 and 20 have been disposed to allow the detection coils 86 to be parallel to the cover glass 57 forming the bottom of the experimental bath 56, the present invention is not limited to such embodiments. For instance, the detection coils 86 of the magnetic sensor heads 18 and 20 may be disposed to be perpendicular to the cover glass 57 forming the bottom of the experimental bath 56. That is, the magnetic sensor heads 18 and 20, especially, the first magnetic sensor head 18 thereof, may be disposed to be close enough to the cellular tissue 50 serving as the detection object to obtain a sufficient spatial resolution; or the magnetic sensor heads 18 and 20 may be disposed such that a relative relation between orientations of magnetic fluxes of the magnetic signals generated by the cellular tissue serving as the detection object and the magnetic sensor heads 18 and 20 satisfies an angle where the magnetic fluxes can be detected by the detecting coil 86, substantially.

Besides, although no illustrative description will be made on every little thing, the present invention may be possibly implemented in other modes in various modification, corrections and improvements or the like on the ground of knowledge of those skilled in the art and it is needles to say that all of such modes are covered within the scope of the present invention unless otherwise departed from objectives of the present invention.

1. A cellular tissue magnetic signal detecting device for detecting a magnetic signal locally generated in a cellular tissue including an excitable cell generating an electrical excitation, the cellular tissue magnetic signal detecting device comprising:
a magnetic sensor head operative to approach the cellular tissue within 1000 μm; and
a magnetic detecting section detecting the magnetic signal with a resolution of 1000 μm or less at a noise level of 1 nT or less, and a response speed of lms or less based on an output signal from the magnetic sensor head;
the magnetic sensor head including magneto impedance sensor.

2. The cellular tissue magnetic signal detecting device according to claim 1, wherein
the magnetic detecting section comprises:
a first magnetic sensor head and a second magnetic sensor head spaced from the cellular tissue in distance longer than a distance between the cellular tissue and the first magnetic sensor head;
and further comprising:
an environmental magnetic field canceling section for eliminating an influence of an environmental magnetic field based on magnetic signals detected by the first magnetic sensor head and the second magnetic sensor head, respectively.

3-7. (canceled)

8. The cellular tissue magnetic signal detecting device according to claim 1, wherein the magnetic sensor heads include columnar magnetic bodies.

9. The cellular tissue magnetic signal detecting device according to claim 2, wherein the magnetic sensor heads include columnar magnetic bodies.

10. The cellular tissue magnetic signal detecting device according to claim 1, wherein the magnetic sensor heads include tabular magnetic bodies or thin-film magnetic bodies.

11. The cellular tissue magnetic signal detecting device according to claim 2, wherein the magnetic sensor heads include tabular magnetic bodies or thin-film magnetic bodies.

12. The cellular tissue magnetic signal detecting device according to claim 1, wherein the magnetic sensor heads include magnetic bodies of mesh-like structures.

13. The cellular tissue magnetic signal detecting device according to claim 2, wherein the magnetic sensor heads include magnetic bodies of mesh-like structures.

14. The cellular tissue magnetic signal detecting device according to claim 1, further comprising:
a stimulus applying section for applying the cellular tissue with at least one of a mechanical stimulus, an electromagnetic wave, a heat and a drug.

15. The cellular tissue magnetic signal detecting device according to claim 2, further comprising:
a stimulus applying section for applying the cellular tissue with at least one of a mechanical stimulus, an electromagnetic wave, a heat and a drug.

16. The cellular tissue magnetic signal detecting device according to claim 8, further comprising:
a stimulus applying section for applying the cellular tissue with at least one of a mechanical stimulus, an electromagnetic wave, a heat and a drug.

17. The cellular tissue magnetic signal detecting device according to claim 9, further comprising:
a stimulus applying section for applying the cellular tissue with at least one of a mechanical stimulus, an electromagnetic wave, a heat and a drug.

18. The cellular tissue magnetic signal detecting device according to claim 10, further comprising:
a stimulus applying section for applying the cellular tissue with at least one of a mechanical stimulus, an electromagnetic wave, a heat and a drug.

19. The cellular tissue magnetic signal detecting device according to claim 11, further comprising:
a stimulus applying section for applying the cellular tissue with at least one of a mechanical stimulus, an electromagnetic wave, a heat and a drug.

20. The cellular tissue magnetic signal detecting device according to claim 12, further comprising:
a stimulus applying section for applying the cellular tissue with at least one of a mechanical stimulus, an electromagnetic wave, a heat and a drug.

21. The cellular tissue magnetic signal detecting device according to claim 13, further comprising:
a stimulus applying section for applying the cellular tissue with at least one of a mechanical stimulus, an electromagnetic wave, a heat and a drug.

22. The cellular tissue magnetic signal detecting device according to claim 1, further comprising:
a cellular tissue sustaining section for sustaining the cellular tissue in a viability state by supplying the cellular tissue with a physiological extracellular fluid, having an ion composition osmotic pressure at temperatures ranging from 0° C. to 42° C.

23. The cellular tissue magnetic signal detecting device according to claim 2, further comprising:
a cellular tissue sustaining section for sustaining the cellular tissue in a viability state by supplying the cellular tissue with a physiological extracellular fluid, having an ion composition osmotic pressure at temperatures ranging from 0° C. to 42° C.

24. The cellular tissue magnetic signal detecting device according to claim 8, further comprising:
a cellular tissue sustaining section for sustaining the cellular tissue in a viability state by supplying the cellular tissue with a physiological extracellular fluid, having an ion composition osmotic pressure at temperatures ranging from 0° C. to 42° C.

25. The cellular tissue magnetic signal detecting device according to claim 9, further comprising:
a cellular tissue sustaining section for sustaining the cellular tissue in a viability state by supplying the cellular tissue with a physiological extracellular fluid, having an ion composition osmotic pressure at temperatures ranging from 0° C. to 42° C.
